(19) United States
(12) Patent Application Publication
(10) Pub. No.: US 2025/0344466 A1
(43) Pub. Date: Nov. 6, 2025

(54) STACKED TRANSISTORS AND METHODS OF FORMING THE SAME

(71) Applicants: Taiwan Semiconductor Manufacturing Co., Ltd., Hsinchu (TW); National Yang Ming Chiao Tung University, Hsinchu City (TW)

(72) Inventors: Hsin-Cheng Lin, Hsinchu (TW); Ching-Wang Yao, Hsinchu (TW); Kung-Ying Chiu, Hsinchu (TW); Chee-Wee Liu, Taipei City (TW)

(21) Appl. No.: 19/271,523

(22) Filed: Jul. 16, 2025

Related U.S. Application Data
(63) Continuation of application No. 18/508,841, filed on Nov. 14, 2023.
(60) Provisional application No. 63/500,004, filed on May 4, 2023.

(51) Int. Cl. H10D 62/10; H10D 30/01; H10D 30/43; H10D 30/67; H10D 62/13; H10D 64/01; H10D 84/01; H10D 84/03; H10D 84/83

(52) U.S. Cl. CPC H10D 62/121; H10D 30/014; H10D 30/43; H10D 30/6735; H10D 30/6757; H10D 62/115; H10D 62/151; H10D 64/017; H10D 84/013; H10D 84/0149; H10D 84/0151; H10D 84/038; H10D 84/83

(57) ABSTRACT

Various embodiments include stacked transistors and methods of forming stacked transistors. In an embodiment, a device includes: a first nanostructure; a second nanostructure above the first nanostructure; a first gate structure extending along a top surface and a bottom surface of the first nanostructure; and a second gate structure extending along a top surface and a bottom surface of the second nanostructure. The first gate structure is disposed at a first side of the first nanostructure and a first side of the second nanostructure. The second gate structure is disposed at a second side of the first nanostructure and a second side of the second nanostructure. The second side of the first nanostructure is opposite the first side of the first nanostructure. The second side of the second nanostructure opposite the first side of the second nanostructure.

### PRIORITY CLAIM AND CROSS-REFERENCE

This application is a continuation of U.S. patent application Ser. No. 18/508,841, filed Nov. 14, 2023, entitled, “Stacked Transistors and Methods of Forming The Same,” which claims the benefit of U.S. Provisional Application No. 63/500,004, filed on May 4, 2023, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a stacked transistor schematic, in accordance with some embodiments.

FIGS. 2A-46B are views of intermediate stages in the manufacturing of stacked transistors, in accordance with some embodiments.

FIGS. 47 and 48 are views of a NAND gate, in accordance with some embodiments.

FIGS. 49A-49B are views of stacked transistors, in accordance with some other embodiments.

FIGS. 50 and 51 are views of a NOR gate, in accordance with some embodiments.

FIGS. 52A-52B are views of stacked transistors, in accordance with some other embodiments.

FIGS. 53 and 54 are views of a NOT gate, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, stacked transistors include multiple lower gate structures and multiple upper gate structures. The lower gate structures are around different lower semiconductor nanostructures, and may be separately controlled. The upper gate structures are around different upper semiconductor nanostructures, and may also be separately controlled. The stacked transistors may be interconnected to form logic devices, such as Boolean logic gates. Because the transistors are stacked, they have a small footprint. Specifically, a resulting Boolean logic gate may have a one-transistor (1T) footprint, even when the Boolean logic gate includes multiple transistors.

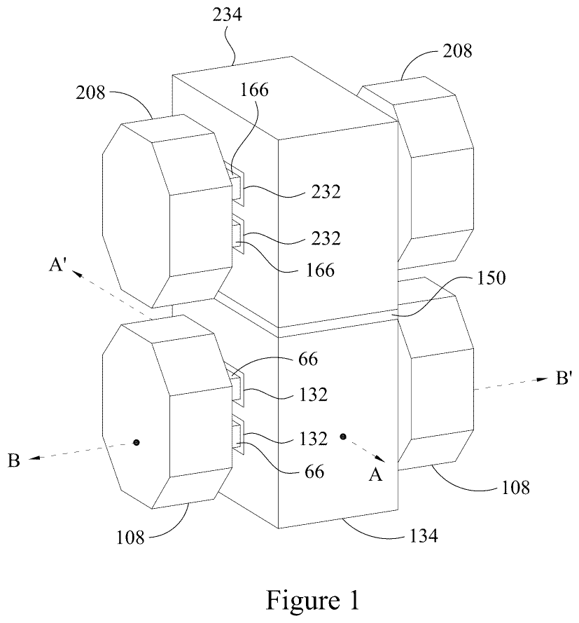

FIG. 1 illustrates an example of a stacked transistor schematic, in accordance with some embodiments. FIG. 1 is a three-dimensional view, where some features of the stacked transistors are omitted for illustration clarity.

The stacked transistors include multiple vertically stacked nanostructure-FETs (e.g., nanowire FETs, nanosheet FETs, multi bridge channel (MBC) FETs, nanoribbon FETs, gate-all-around (GAA) FETs, or the like). For example, the stacked transistors may include lower nanostructure-FET(s) of a first device type (e.g., n-type/p-type) and upper nanostructure-FET(s) of a second device type (e.g., p-type/n-type) that is opposite the first device type. Specifically, the stacked transistors may include lower PMOS transistors and upper NMOS transistors, or the stacked transistors may include lower NMOS transistors and upper PMOS transistors. The nanostructure-FETs include semiconductor nanostructures (including lower semiconductor nanostructures 66 and upper semiconductor nanostructures 166), where the semiconductor nanostructures act as channel regions for the nanostructure-FETs. The semiconductor nanostructures may be nanosheets, nanowires, or the like. The lower semiconductor nanostructures 66 are for the lower nanostructure-FETs and the upper semiconductor nanostructures 166 are for the upper nanostructure-FETs.

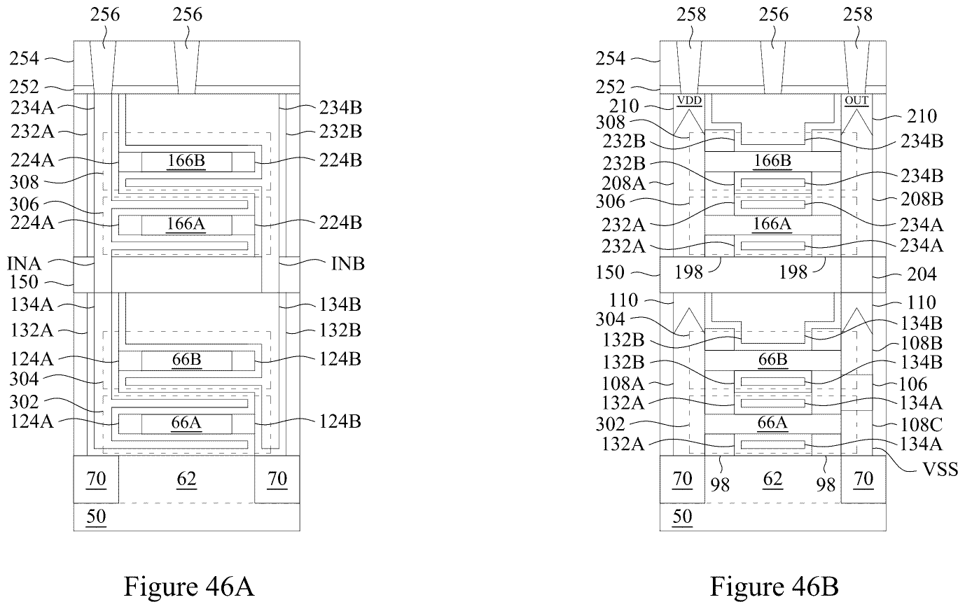

Gate dielectrics (including lower gate dielectrics 132 and upper gate dielectrics 232) are along multiple surfaces (including top surfaces and bottom surfaces of the semiconductor nanostructures). Gate electrodes (including lower gate electrodes 134 and upper gate electrodes 234) are over the gate dielectrics and around the semiconductor nanostructures. Source/drain regions (including lower epitaxial source/drain regions 108 and upper epitaxial source/drain regions 208) are disposed at opposing sides of the gate dielectrics and the gate electrodes. Source/drain region(s) may refer to a source or a drain, individually or collectively dependent upon the context. Isolation features may be formed to separate desired ones of the source/drain regions and/or desired ones of the gate electrodes. For example, a lower gate electrode 134 may optionally be separated from an upper gate electrode 234 by an isolation dielectric 150. Further, the upper epitaxial source/drain regions 208 may be separated from lower epitaxial source/drain regions 108 by the isolation dielectric 150 (not explicitly illustrated in FIG. 1, see FIGS. 46A-46B). The isolation features between channel regions, gates, and source/drain regions allow for vertically stacked transistors, thereby improving device density. Because of the vertically stacked nature of stacked transistors, the schematic may also be referred to as folding transistors.

FIG. 1 further illustrates reference cross-sections that are used in later figures. Cross-section A-A′ is along a longitudinal axis of a gate electrode of a stacked transistor. Cross-section B-B′ is perpendicular to cross-section A-A′ and is parallel to a longitudinal axis of the semiconductor nanostructures of a stacked transistor and in a direction of, for example, a current flow between the source/drain regions of the stacked transistor. Subsequent figures refer to these reference cross-sections for clarity.

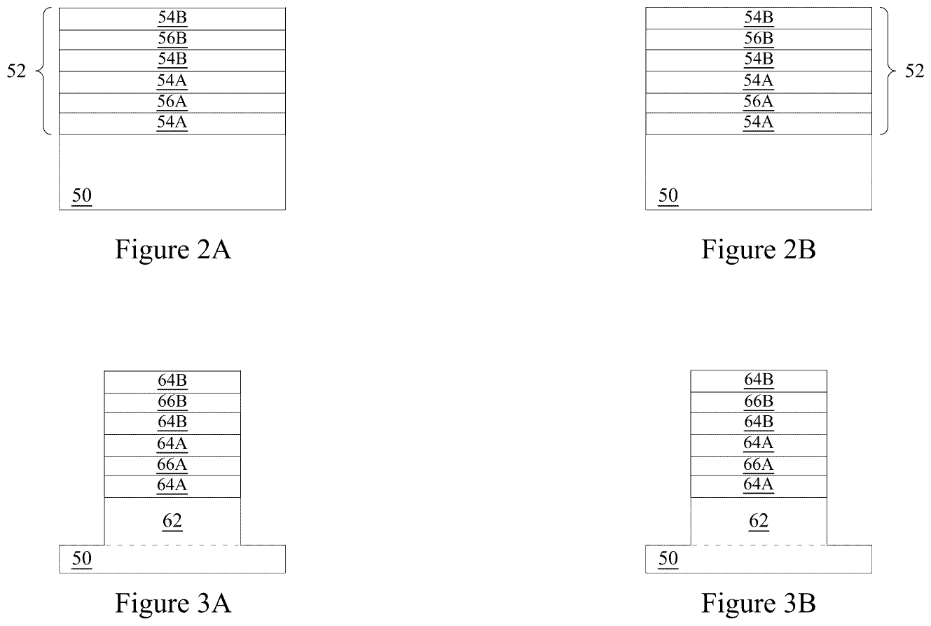

FIGS. 2A-46B are views of intermediate stages in the manufacturing of stacked transistors, in accordance with some embodiments. FIGS. 2A, 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, 33A, 34A, 35A, 36A, 37A, 38A, 39A, 40A, 41A, 42A, 43A, 44A, 45A, and 46A illustrate cross-sectional views along a similar cross-section as reference cross-section A-A′ in FIG. 1. FIGS. 2B, 3B, 4B, 5B, 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, 29B, 30B, 31B, 32B, 33B, 34B, 35B, 36B, 37B, 38B, 39B, 40B, 41B, 42B, 43B, 44B, 45B, and 46B illustrate cross-sectional views along a similar cross-section as reference cross-section B-B′ in FIG. 1.

In FIGS. 2A-2B, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A lower multi-layer stack 52 is formed over the substrate 50. The lower multi-layer stack 52 includes lower dummy layers (including first lower dummy layers 54A and second lower dummy layers 54B) and lower semiconductor layers (including a first lower semiconductor layer 56A and a second lower semiconductor layer 56B). The first lower semiconductor layer 56A is between the first lower dummy layers 54A. The second lower semiconductor layer 56B is between the second lower dummy layers 54B. As subsequently described in greater detail, the lower dummy layers 54 will be removed and the lower semiconductor layers 56 will be patterned to form channel regions of stacked transistors. Specifically, the first lower semiconductor layer 56A will be patterned to form a first channel region of a first lower nanostructure-FET of the stacked transistors, and the second lower semiconductor layer 56B will be patterned to form a second channel region of a second lower nanostructure-FET of the stacked transistors.

The lower multi-layer stack 52 is illustrated as including four of the lower dummy layers 54 and two of the lower semiconductor layers 56. It should be appreciated that the lower multi-layer stack 52 may include any number of the lower dummy layers 54 and the lower semiconductor layers 56. Each layer of the lower multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first lower dummy layers 54A are formed of a first semiconductor material, and the second lower dummy layers 54B is formed of a second semiconductor material. The first and second semiconductor materials may be selected from the candidate semiconductor materials of the substrate 50. The first and second semiconductor materials have a high etching selectivity to one another. As such, the material of the first lower dummy layers 54A may be removed at a faster rate than the material of the second lower dummy layers 54B in subsequent processing. In some embodiments, the first lower dummy layers 54A are formed of silicon-germanium having a high germanium concentration (e.g., a germanium concentration in the range of 75% to 95%, such as about 80%) and the second lower dummy layers 54B are formed of silicon-germanium having a low germanium concentration (e.g., a germanium concentration in the range of 50% to 65%, such as about 60%).

The lower semiconductor layers 56 (including the first lower semiconductor layer 56A and the second lower semiconductor layer 56B) are formed of a semiconductor material. The semiconductor material may be selected from the candidate semiconductor materials of the substrate 50. In some embodiments, the first lower semiconductor layer 56A and the second lower semiconductor layer 56B are both formed of a semiconductor material suitable for n-type devices, such as silicon, germanium, a group III-V material, or the like. In some embodiments, the first lower semiconductor layer 56A and the second lower semiconductor layer 56B are both formed of a semiconductor material suitable for p-type devices, such as silicon-germanium, germanium-tin, tin, silicon-germanium-tin, or the like. The semiconductor material of the lower semiconductor layers 56 have a high etching selectivity to the semiconductor materials of the lower dummy layers 54. As such, the materials of the lower dummy layers 54 may be removed at a faster rate than the material of the lower semiconductor layers 56 in subsequent processing. In some embodiments, the lower semiconductor layers 56 are formed of silicon, which may be undoped or lightly doped at this step of processing.

Some layers of the lower multi-layer stack 52 may be thicker than other layers of the lower multi-layer stack 52. For example, the thickness of the lower dummy layers 54 may (or may not) be different than the thickness of the lower semiconductor layers 56. Further, the thickness of the first lower semiconductor layer 56A may (or may not) be different than the thickness of the second lower semiconductor layer 56B. In some embodiments, the thickness of each of the lower semiconductor layers 56 is in the range of 1 nm to 50 nm.

In FIGS. 3A-3B, a semiconductor fin 62 is formed in the substrate 50. Additionally, lower nanostructures 64, 66 (including first lower dummy nanostructures 64A, second lower dummy nanostructures 64B, a first lower semiconductor nanostructure 66A, and a second lower semiconductor nanostructure 66B) are formed in the lower multi-layer stack 52. In some embodiments, the lower nanostructures 64, 66 and the semiconductor fin 62 may be formed in the lower multi-layer stack 52 and the substrate 50 by etching trenches in the lower multi-layer stack 52 and the substrate 50. The etching may be any acceptable etch process, such as a reactive ion etch (RIE), neutral beam etch (NBE), the like, or a combination thereof. The etching may be anisotropic. Forming the lower nanostructures 64, 66 by etching the lower multi-layer stack 52 may define the first lower dummy nanostructures 64A from the first lower dummy layers 54A, the second lower dummy nanostructures 64B from the second lower dummy layers 54B, the first lower semiconductor nanostructure 66A from the first lower semiconductor layer 56A, and the second lower semiconductor nanostructure 66B from the second lower semiconductor layer 56B. The first lower dummy nanostructures 64A and the second lower dummy nanostructures 64B may further be collectively referred to as the lower dummy nanostructures 64. The first lower semiconductor nanostructure 66A and the second lower semiconductor nanostructure 66B may further be collectively referred to as the lower semiconductor nanostructures 66.

As subsequently described in greater detail, various one of the lower nanostructures 64, 66 will be removed to form channel regions of stacked transistors. Specifically, the first lower semiconductor nanostructure 66A will act as a channel region for a first lower nanostructure-FET of the stacked transistors. Additionally, the second lower semiconductor nanostructure 66B will act as a channel region for a second lower nanostructure-FET of the stacked transistors.

The semiconductor fin 62 and the lower nanostructures 64, 66 may be patterned by any suitable method. For example, the semiconductor fin 62 and the lower nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and one of the remaining spacers may then be used to pattern the semiconductor fin 62 and the lower nanostructures 64, 66. In some embodiments, a mask (or other layer) may remain on the lower nanostructures 64, 66.

Although each of the semiconductor fin 62 and the lower nanostructures 64, 66 are illustrated as having a constant width throughout, in other embodiments, the semiconductor fin 62 and/or the lower nanostructures 64, 66 may have tapered sidewalls such that a width of each of the semiconductor fin 62 and/or the lower nanostructures 64, 66 continuously increases in a direction towards the substrate 50. In such embodiments, each of the lower nanostructures 64, 66 may have a different width and be trapezoidal in shape. Alternatively, each of the lower nanostructures 64, 66 may be rectangular in shape, square in shape, diamond in shape, circular in shape, elliptical in shape, or the like. Further, each of the lower nanostructures 64, 66 may (or may not) have rounded corners, either at this step or after subsequent processing step(s). In some embodiments, the width/diameter of the lower semiconductor nanostructures 66 is in the range of 1 nm to 50 nm.

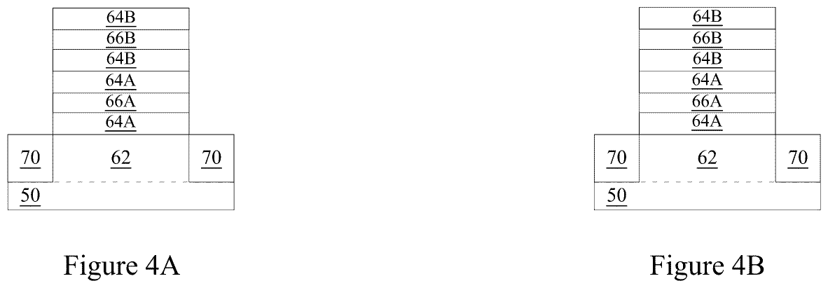

In FIGS. 4A-4B, isolation regions 70 are formed adjacent the semiconductor fin 62. The isolation regions 70 may be formed by depositing an insulating material over the substrate 50, the semiconductor fin 62, and lower nanostructures 64, 66. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the lower nanostructures 64, 66. Although the insulating material is illustrated as a single layer, some embodiments may utilize multiple layers. For example, in some embodiments a liner (not separately illustrated) may first be formed along a surface of the substrate 50, the semiconductor fin 62, and the lower nanostructures 64, 66. Thereafter, a fill material, such as one of the previously described insulating materials may be formed over the liner.

A removal process is then applied to the insulating material to remove excess insulating material over the lower nanostructures 64, 66. In some embodiments, a planarization process such as a chemical mechanical polish (CMP), an etch-back process, combinations thereof, or the like may be utilized. The planarization process exposes the lower nanostructures 64, 66 such that top surfaces of the lower nanostructures 64, 66 and the insulating material are level after the planarization process is complete.

The insulating material is then recessed to form the isolation regions 70. The insulating material is recessed such that at least the lower nanostructures 64, 66 protrude from between neighboring isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an etching process, such as one that is selective to the insulating material (e.g., selectively etches the insulating material at a faster rate than the materials of the semiconductor fin 62 and the lower nanostructures 64, 66). For example, an oxide removal using, for example, dilute hydrofluoric (dHF) acid may be used.

The previously described process is just one example of how the semiconductor fin 62 and the lower nanostructures 64, 66 may be formed. In some embodiments, the semiconductor fin 62 and/or the lower nanostructures 64, 66 may be formed using a mask and an epitaxial growth process. For example, a dielectric layer can be formed over a top surface of the substrate 50, and a trench can be etched through the dielectric layer to expose the underlying substrate 50. Epitaxial structures can be epitaxially grown in the trench, and the dielectric layer can be recessed such that the epitaxial structures protrude from the dielectric layer to form the semiconductor fin 62 and/or the lower nanostructures 64, 66. The epitaxial structures may comprise the previously described alternating semiconductor materials. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the lower semiconductor nanostructures 66. For example, an n-type impurity implant and/or a p-type impurity implant may be performed, or the semiconductor materials may be in situ doped during growth. The n-type impurities may be phosphorus, arsenic, antimony, or the like at a concentration in a range from 10¹⁷ atoms/cm³ to 10¹⁹ atoms/cm³. The p-type impurities may be boron, boron fluoride, indium, gallium, or the like at a concentration in a range from 10¹⁷ atoms/cm³ to 10¹⁹ atoms/cm³. Other acceptable impurities may be utilized. The wells in the lower semiconductor nanostructures 66 have a conductivity type opposite from a conductivity type of lower source/drain regions that will be subsequently formed adjacent the lower semiconductor nanostructures 66.

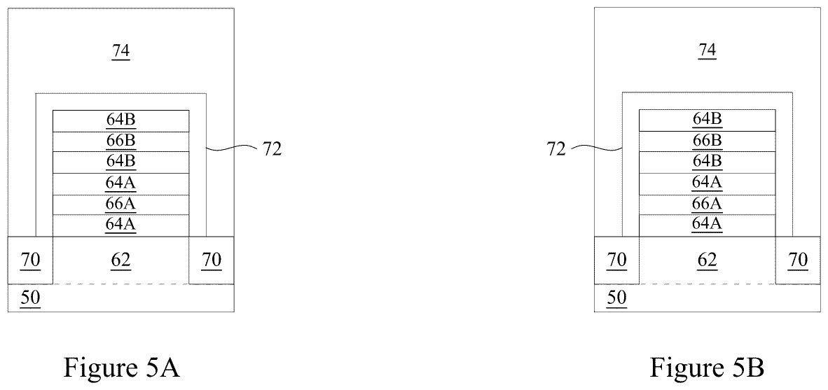

In FIGS. 5A-5B, a lower dummy dielectric layer 72 is formed on the semiconductor fin 62 and/or the lower nanostructures 64, 66. The lower dummy dielectric layer 72 may be, for example, silicon oxide, silicon nitride, a combination thereof, or the like, and may be deposited or thermally grown according to acceptable techniques. A lower dummy gate layer 74 is formed over the lower dummy dielectric layer 72. The lower dummy gate layer 74 may be deposited over the lower dummy dielectric layer 72 and then planarized, such as by a CMP. The lower dummy gate layer 74 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The lower dummy gate layer 74 may be deposited by physical vapor deposition (PVD), CVD, sputter deposition, or other techniques for depositing the selected material. The lower dummy gate layer 74 may be formed of other materials that have a high etching selectivity to insulating materials. A mask layer (not separately illustrated) may be deposited over the lower dummy gate layer 74. The mask layer may include, for example, silicon nitride, silicon oxynitride, or the like. In the illustrated embodiment, the lower dummy dielectric layer 72 covers only the lower nanostructures 64, 66. In another embodiment, the lower dummy dielectric layer 72 covers the isolation regions 70, such that the lower dummy dielectric layer 72 extends between the lower dummy gate layer 74 and the isolation regions 70.

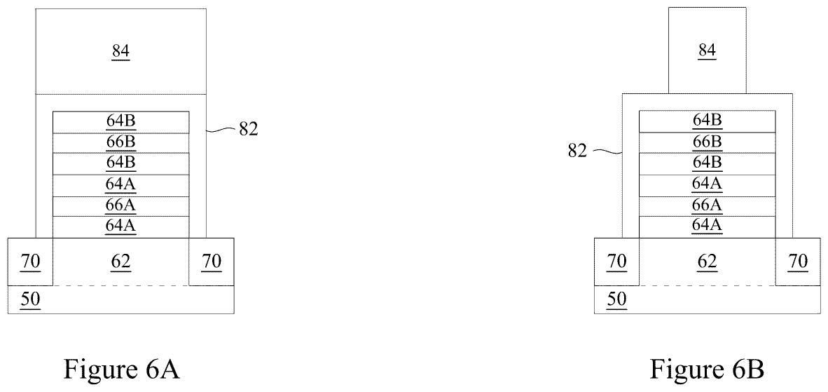

In FIGS. 6A-6B, the lower dummy gate layer 74 is patterned to form a lower dummy gate 84. For example, when a mask layer is formed over the lower dummy gate layer 74, the mask layer may be patterned using acceptable photolithography and etching techniques to form a mask. The pattern of the mask then may be transferred to the lower dummy gate layer 74 and to the lower dummy dielectric layer 72 to form the lower dummy gate 84 and a lower dummy dielectric 82, respectively. Optionally, portions of the lower dummy gate layer 74 covering the isolation regions 70 may be removed. The lower dummy gate 84 covers respective channel regions of the lower nanostructures 64, 66. The mask can optionally be removed after patterning, such as by any acceptable etching technique.

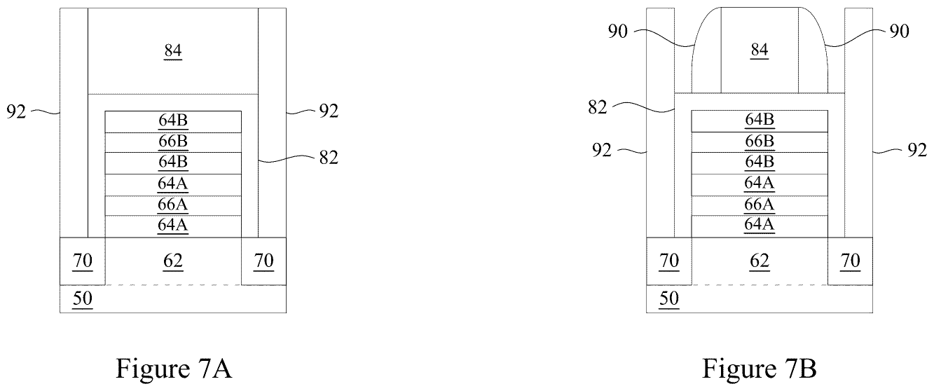

In FIGS. 7A-7B, lower gate spacers 90 are formed over the lower nanostructures 64, 66 and on exposed sidewalls of the lower dummy gate 84. The lower gate spacers 90 may be formed on the lower dummy dielectric 82. The lower gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the lower dummy gate 84 (thus forming the lower gate spacers 90).

Further, implants for lightly doped source/drain (LDD) regions (not separately illustrated) may be performed. The LDD implants may be performed before the lower gate spacers 90 are formed. Appropriate type impurities may be implanted into the lower nanostructures 64, 66 to a desired depth. The LDD regions may have a same conductivity type as a conductivity type of source/drain regions that will be subsequently formed adjacent the lower semiconductor nanostructures 66. In some embodiments, the lower semiconductor nanostructures 66 include p-type LDD regions. In some embodiments, the lower semiconductor nanostructures 66 include n-type LDD regions. The n-type impurities may be the any of the n-type impurities previously discussed, and the p-type impurities may be the any of the p-type impurities previously discussed. The lightly doped source/drain regions may have a concentration of impurities in a range from 10¹⁷ atoms/cm³ to 10²⁰ atoms/cm³. An anneal may be used to repair implant damage and to activate the implanted impurities. In some embodiments, the grown materials of the lower nanostructures 64, 66 may be in situ doped during growth, which may obviate the implantations, although in situ and implantation doping may be used together.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like.

A lower mask 92 may be formed over the isolation regions 70 and around the lower nanostructures 64, 66 (e.g., on the sidewalls of the lower dummy dielectric 82 and the lower dummy gate 84 in the cross-section of FIG. 7A). The lower mask 92 may be used as an etching mask during the etching processes for forming the lower gate spacers 90. Thus, the lower gate spacers 90 may not be formed on the sidewalls of the lower dummy gate 84 in the cross-section of FIG. 7A. The lower mask 92 may include a hardmask. In some embodiments, the lower mask 92 is formed of a photoresist. The photoresist may be formed by spin coating, a deposition process such as CVD, combinations thereof, or the like, and can be patterned using any acceptable photolithography techniques to have a desired pattern of the lower gate spacers 90.

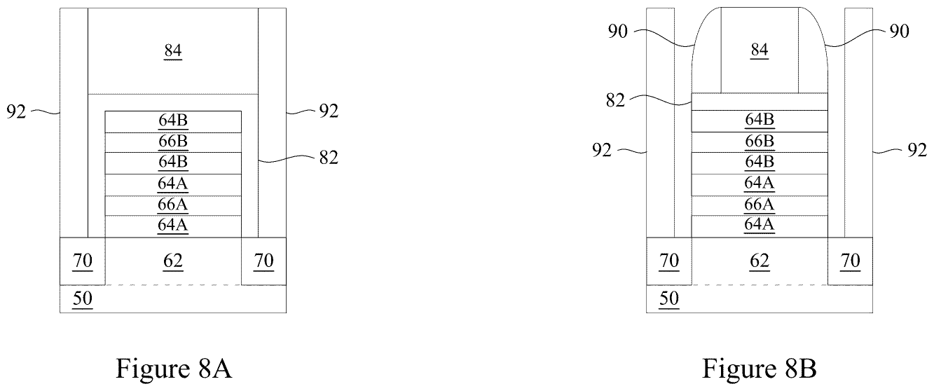

In FIGS. 8A-8B, the lower dummy dielectric 82 is patterned to expose the sidewalls of the lower nanostructures 64, 66 in the cross-section of FIG. 8B. The lower dummy dielectric 82 may be patterned using a suitable etching process, using the lower mask 92 and the lower gate spacers 90 as an etching mask. The etching may be any acceptable etch process, such as a reactive ion etch (RIE), neutral beam etch (NBE), the like, or a combination thereof. The etching may be anisotropic. After the etching, the sidewalls of the lower nanostructures 64, 66, the lower dummy dielectric 82, and the lower gate spacers 90 may be laterally coterminous in the cross-section of FIG. 8B. The etching may expose the isolation regions 70.

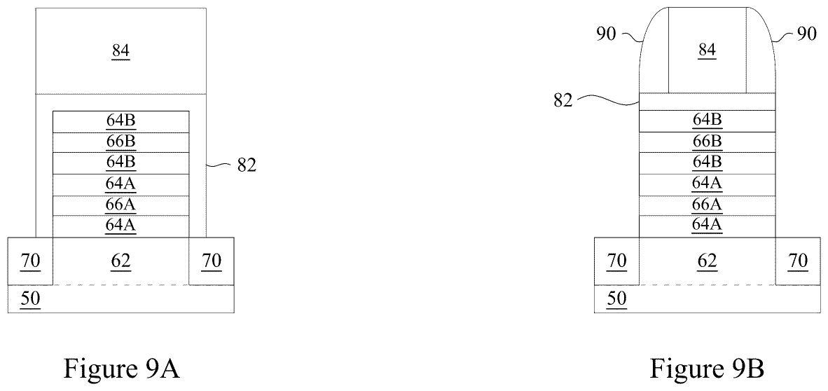

In FIGS. 9A-9B, the lower mask 92 is removed to expose the isolation regions 70. In embodiments where the lower mask 92 includes a photoresist, the photoresist may be removed with an ashing process.

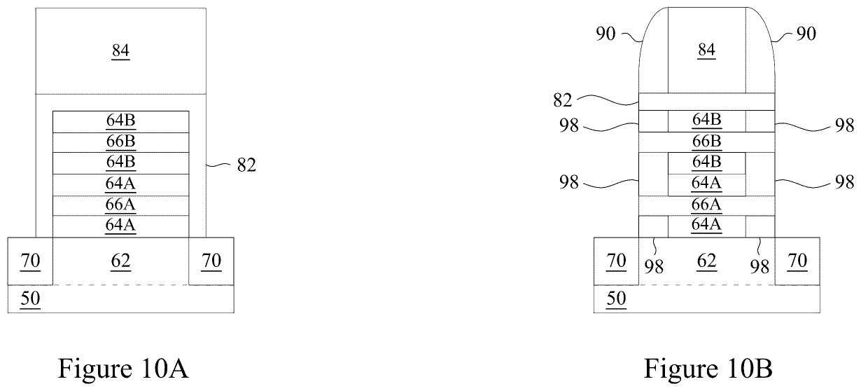

In FIGS. 10A-10B, lower inner spacers 98 are formed on the sidewalls of the lower dummy nanostructures 64. As subsequently described in greater detail, source/drain regions will be formed adjacent the lower semiconductor nanostructures 66, and the lower dummy nanostructures 64 will be replaced with corresponding gate structures. The lower inner spacers 98 act as isolation features between the subsequently formed source/drain regions and the subsequently formed gate structures.

As an example to form the lower inner spacers 98, portions of the sidewalls of the lower dummy nanostructures 64 are recessed in the cross-section of FIG. 10B to form sidewall recesses. The sidewalls may be recessed by any acceptable etch process, such as one that is selective to the materials of the lower dummy nanostructures 64 (e.g., selectively etches the material of the first lower dummy nanostructures 64A and the material of the second lower dummy nanostructures 64B at a faster rate than the material(s) of the lower semiconductor nanostructures 66). The etching may be isotropic. Although sidewalls of the lower dummy nanostructures 64 are illustrated as being straight, the sidewalls may be concave or convex. The lower dummy dielectric 82 covers the sidewalls of the lower dummy nanostructures 64 in the cross-section of FIG. 10A during the etching. An insulating material may then be conformally formed in the sidewall recesses. The insulating material may be silicon nitride, silicon oxynitride, silicon oxycarbonitride, or the like. Other low-dielectric constant (low-k) materials having a k-value less than about 3.5 may be utilized. The insulating material of the lower inner spacers 98 has a high etching selectivity to the semiconductor material of the lower dummy nanostructures 64. The insulating material may be formed by a deposition process, such as ALD, CVD, or the like. The insulating material may then be etched. The etching of the insulating material may be anisotropic. For example, the etch process may be a dry etch such as a RIE, a NBE, or the like. The insulating material, when etched, has portions remaining in the sidewall recesses (thus forming the lower inner spacers 98). Although outer sidewalls of the lower inner spacers 98 are illustrated as being flush with the sidewalls of the lower semiconductor nanostructures 66, the outer sidewalls of the lower inner spacers 98 may extend beyond or be recessed from the sidewalls of the lower semiconductor nanostructures 66. Thus, the lower inner spacers 98 may partially fill, completely fill, or overfill the sidewall recesses. Moreover, although the sidewalls of the lower inner spacers 98 are illustrated as being straight, the sidewalls of the lower inner spacers 98 may be concave or convex.

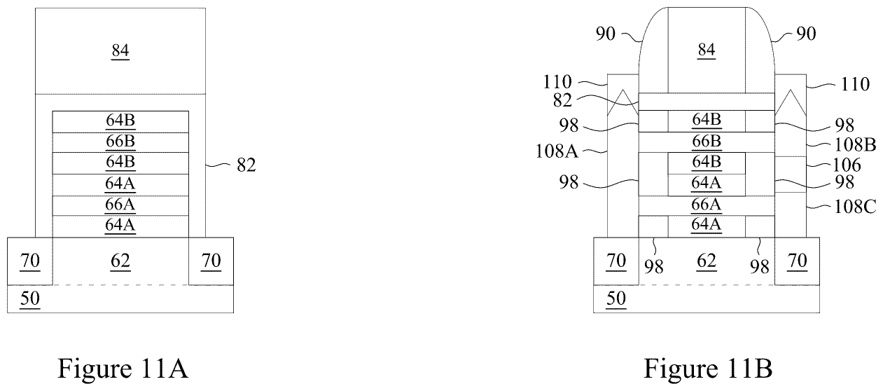

In FIGS. 11A-11B, lower epitaxial source/drain regions 108 are formed on the sidewalls of the lower semiconductor nanostructures 66. The lower dummy dielectric 82 masks the lower semiconductor nanostructures 66 in the cross-section of FIG. 11A, so that the lower epitaxial source/drain regions 108 are on the sidewalls of the lower semiconductor nanostructures 66 in the cross-section of FIG. 11B. In some embodiments, the lower epitaxial source/drain regions 108 exert stress in the respective channel regions of the lower semiconductor nanostructures 66, thereby improving performance. The lower epitaxial source/drain regions 108 are formed such that the lower semiconductor nanostructures 66 are disposed between the lower epitaxial source/drain regions 108. In some embodiments, the lower inner spacers 98 are used to separate the lower epitaxial source/drain regions 108 from the lower dummy nanostructures 64 by an appropriate lateral distance so that the lower epitaxial source/drain regions 108 do not short out with subsequently formed gates of the resulting devices.

The lower epitaxial source/drain regions 108 may be grown laterally from exposed sidewalls of the lower semiconductor nanostructures 66. The lower epitaxial source/drain regions 108 have a conductivity type that is suitable for the device type of the lower nanostructure-FETs. In some embodiments, the lower epitaxial source/drain regions 108 are n-type source/drain regions. For example, if the lower semiconductor nanostructures 66 are silicon, the lower epitaxial source/drain regions 108 may include materials exerting a tensile strain on the lower semiconductor nanostructures 66, such as silicon, silicon carbide, phosphorous-doped silicon, silicon phosphide, silicon arsenide, antimony-doped silicon, combinations thereof, or the like. In some embodiments, the lower epitaxial source/drain regions 108 are p-type source/drain regions. For example, if the lower semiconductor nanostructures 66 are silicon, the lower epitaxial source/drain regions 108 may include materials exerting a compressive strain on the lower semiconductor nanostructures 66, such as silicon-germanium, boron-doped silicon-germanium, gallium-doped silicon-germanium, boron-doped silicon, germanium, germanium-tin, combinations thereof, or the like. The lower epitaxial source/drain regions 108 may have surfaces raised from respective upper surfaces of the lower semiconductor nanostructures 66 and may have facets.

The lower epitaxial source/drain regions 108 may be implanted with dopants to form source/drain regions, similar to the process previously discussed for forming lightly doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the lower epitaxial source/drain regions 108 are in situ doped during growth.

As a result of the epitaxy processes used to form the lower epitaxial source/drain regions 108, upper surfaces of the lower epitaxial source/drain regions 108 have facets which expand laterally outward beyond sidewalls of the lower nanostructures 64, 66. In some embodiments, adjacent lower epitaxial source/drain regions 108 remain separated after the epitaxy process is completed. In other embodiments, these facets cause adjacent lower epitaxial source/drain regions 108 of a same nanostructure-FET to merge (not separately illustrated). The growth of the lower epitaxial source/drain regions 108 may extend to the surface of the isolation regions 70.

The lower epitaxial source/drain regions 108 may comprise one or more semiconductor layers. For example, the lower epitaxial source/drain regions 108 may comprise a first semiconductor layer, a second semiconductor layer, and a third semiconductor layer. Any number of semiconductor layers may be used for the lower epitaxial source/drain regions 108. Each of the first semiconductor layer, the second semiconductor layer, and the third semiconductor layer may be formed of different semiconductor materials and may be doped to different dopant concentrations. In some embodiments, the first semiconductor layer has a dopant concentration less than the second semiconductor layer and greater than the third semiconductor layer. In embodiments in which the lower epitaxial source/drain regions 108 comprise three semiconductor layers, the first semiconductor layer may be grown from semiconductor features (e.g., the lower semiconductor nanostructures 66), the second semiconductor layer may be grown on the first semiconductor layer, and the third semiconductor layer may be grown on the second semiconductor layer.

Further, lower source/drain contacts 110 are formed for the lower epitaxial source/drain regions 108. The lower source/drain contacts 110 may be physically and electrically coupled to the lower epitaxial source/drain regions 108. A liner (not separately illustrated), such as a diffusion barrier layer, an adhesion layer, or the like, and a conductive material are formed on the lower epitaxial source/drain regions 108. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the lower gate spacers 90 and the lower dummy gate 84. The remaining liner and conductive material form the lower source/drain contacts 110 on the lower epitaxial source/drain regions 108. In some embodiments, an etch-back process or the like is utilized.

In this embodiment, the lower epitaxial source/drain regions 108 include a first lower epitaxial source/drain region 108A, a second lower epitaxial source/drain region 108B, and a third lower epitaxial source/drain region 108C. The first lower epitaxial source/drain region 108A is on sidewalls of both the first lower semiconductor nanostructure 66A and the second lower semiconductor nanostructure 66B. The second lower epitaxial source/drain region 108B is formed on a sidewall of the second lower semiconductor nanostructure 66B. The third lower epitaxial source/drain region 108C is formed on a sidewall of the first lower semiconductor nanostructure 66A. The first lower epitaxial source/drain region 108A is opposite each of the second lower epitaxial source/drain region 108B and the third lower epitaxial source/drain region 108C. Thus, the first lower epitaxial source/drain region 108A will be shared between a first lower nanostructure-FET and a second lower nanostructure-FET. The lower source/drain contacts 110 for the second lower epitaxial source/drain region 108B and the third lower epitaxial source/drain region 108C may be formed in different cross-sections.

A lower isolation dielectric 106 may be formed between the second lower epitaxial source/drain region 108B and the third lower epitaxial source/drain region 108C. The lower isolation dielectric 106 acts as an isolation feature between the second lower epitaxial source/drain region 108B and the third lower epitaxial source/drain region 108C. The lower isolation dielectric 106 may be formed by conformally forming a dielectric material on the third lower epitaxial source/drain region 108C using suitable masking and deposition techniques, then subsequently recessing the dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to recess the dielectric material. The etching may be anisotropic. The dielectric material, when etched, has portions left on the third lower epitaxial source/drain region 108C (thus forming the lower isolation dielectric 106).

Various ones of the lower epitaxial source/drain regions 108 may be formed by distinct processes. For example, the third lower epitaxial source/drain region 108C may be formed, the lower isolation dielectric 106 may be subsequently formed over the third lower epitaxial source/drain region 108C, and the second lower epitaxial source/drain region 108B may be subsequently formed over the lower isolation dielectric 106. The first lower epitaxial source/drain region 108A may be formed separately from (e.g., before or after) the third lower epitaxial source/drain region 108C, the lower isolation dielectric 106, and the second lower epitaxial source/drain region 108B. Various masking steps may be used to mask and expose appropriate regions when using distinct processes.

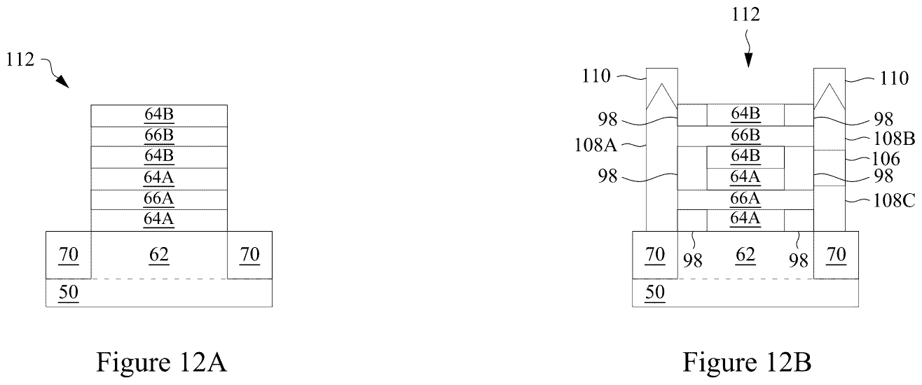

In FIGS. 12A-12B, the lower dummy gate 84 is removed in one or more etching steps, so that a recess 112 is formed between the lower epitaxial source/drain regions 108. Portions of the lower dummy dielectric 82 in the recess 112 are also removed. In some embodiments, the lower dummy gate 84 and the lower dummy dielectric 82 are removed by an anisotropic dry etch process. For example, the etching process may include a dry etch process using reaction gas(es) that selectively etch the material of the lower dummy gate 84 at a faster rate than the materials of the isolation regions 70 and the lower source/drain contacts 110. Optionally, the lower gate spacers 90 may also be removed during the formation of the recess 112. The recess 112 exposes and/or overlies portions of the lower semiconductor nanostructures 66 which act as the channel regions in the resulting devices. The portions of the lower semiconductor nanostructures 66 which act as the channel regions are disposed between neighboring pairs of the lower epitaxial source/drain regions 108. During the removal, the lower dummy dielectric 82 may be used as an etch stop layer when the lower gate spacers 90 and/or the lower dummy gate 84 are etched. The lower dummy dielectric 82 may then be removed after the removal of the lower gate spacers 90 and/or the lower dummy gate 84.

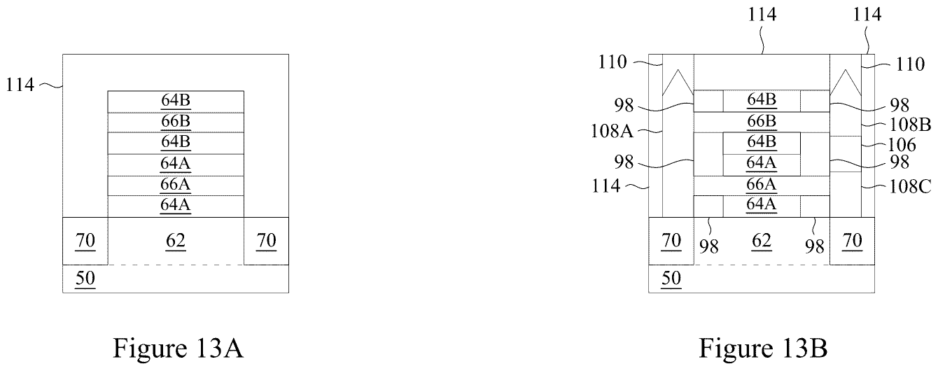

In FIGS. 13A-13B, a lower dielectric 114 is formed in the recess 112, such as over the lower nanostructures 64, 66. The lower dielectric 114 may also be formed around the lower epitaxial source/drain regions 108. The lower dielectric 114 may be formed of a dielectric material, which may be deposited by any suitable method, such as CVD, plasma-enhanced chemical vapor deposition (PECVD), or FCVD. Dielectric materials may include silicon oxycarbide, silicon oxycarbonitride, silicon oxide, or the like. Other dielectric materials formed by any acceptable process may be used.

A removal process is performed to level the top surfaces of the lower dielectric 114 with the top surfaces of the lower source/drain contacts 110. In some embodiments, a planarization process such as a chemical mechanical polish (CMP), an etch-back process, combinations thereof, or the like may be utilized. After the planarization process, top surfaces of the lower dielectric 114 and the lower source/drain contacts 110 are substantially coplanar (within process variations). The lower dielectric 114 covers the lower nanostructures 64, 66.

As subsequently described in greater detail, a first lower gate structure will be formed around the first lower semiconductor nanostructure 66A, while a second lower gate structure will be formed around the second lower semiconductor nanostructure 66B. The first lower gate structure and the second lower gate structure will be disposed at opposing sides of the lower semiconductor nanostructures 66. The first lower gate structure is for a first lower nanostructure-FET while the second lower gate structure is for a second lower nanostructure-FET. The second lower nanostructure-FET will be stacked over the first lower nanostructure-FET.

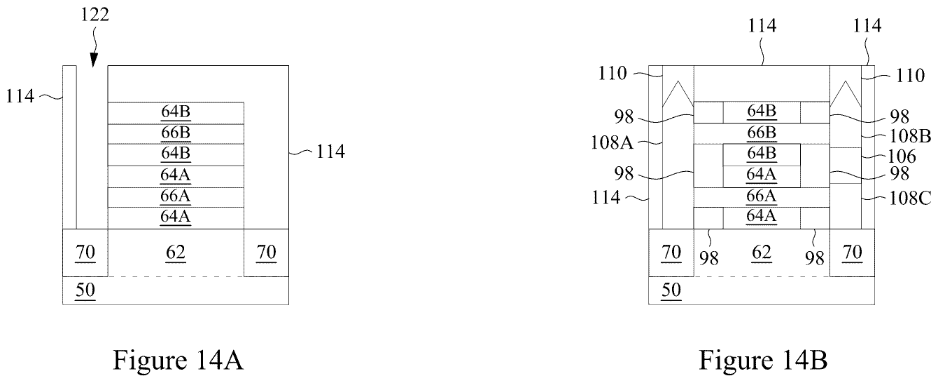

In FIGS. 14A-14B, a recess 122 is formed in the lower dielectric 114 to expose first sidewalls of the lower nanostructures 64, 66. The first sidewalls are at a first side of the lower nanostructures 64, 66 in the cross-section of FIG. 14A. Second sidewalls of the lower nanostructures 64, 66 opposite the first sidewalls remain covered by the lower dielectric 114 at this step. The recess 122 may be formed using an etching process, such as one that is selective to the lower dielectric 114 (e.g., selectively etches the dielectric material of the lower dielectric 114 at a faster rate than the materials of the lower nanostructures 64, 66).

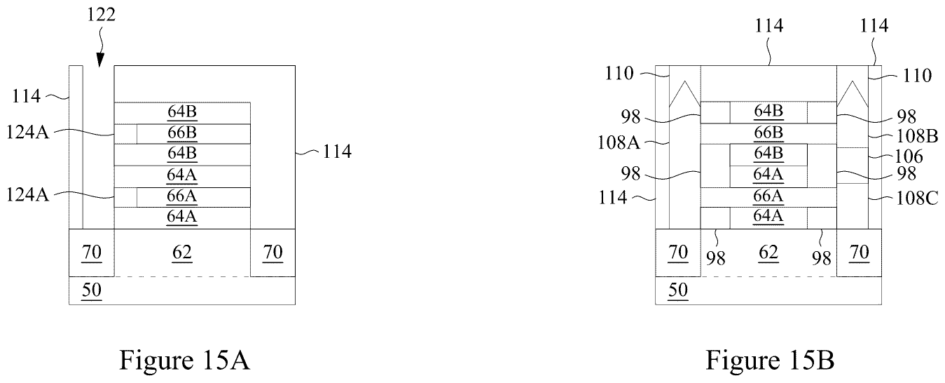

In FIGS. 15A-15B, first lower inner spacers 124A are formed on the sidewalls of the lower semiconductor nanostructures 66. As subsequently described in greater detail, a first lower gate structure will be formed around the first lower semiconductor nanostructure 66A. The first lower inner spacers 124A act as isolation features between the subsequently formed first lower gate structure and the second lower semiconductor nanostructure 66B.

As an example to form the first lower inner spacers 124A, portions of the sidewalls of the lower semiconductor nanostructures 66 exposed in the recess 122 are recessed in the cross-section of FIG. 15A to form sidewall recesses. The sidewalls may be recessed by any acceptable etch process, such as one that is selective to the materials of the lower semiconductor nanostructures 66 (e.g., selectively etches the material of the first lower semiconductor nanostructures 66A and the material of the second lower semiconductor nanostructures 66B at a faster rate than the materials of the lower dummy nanostructures 64 and the lower inner spacers 98). The etching may be isotropic. Although sidewalls of the lower semiconductor nanostructures 66 are illustrated as being straight, the sidewalls may be concave or convex. An insulating material may then be conformally formed in the sidewall recesses. The insulating material may be a carbon-containing dielectric material, such as silicon borocarbonitride, silicon oxycarbonitride, silicon oxycarbide, silicon oxynitride, or the like. Other low-dielectric constant (low-k) materials having a k-value less than about 3.5 may be utilized. The insulating material of the first lower inner spacers 124A has a high etching selectivity to the semiconductor material of the lower dummy nanostructures 64 and the insulating material of the lower inner spacers 98. The insulating material may be formed by a deposition process, such as ALD, CVD, or the like. The insulating material may then be etched. The etching of the insulating material may be anisotropic. For example, the etch process may be a dry etch such as a RIE, a NBE, or the like. The insulating material, when etched, has portions remaining in the sidewall recesses (thus forming the first lower inner spacers 124A). Although outer sidewalls of the first lower inner spacers 124A are illustrated as being flush with the sidewalls of the lower dummy nanostructures 64, the outer sidewalls of the first lower inner spacers 124A may extend beyond or be recessed from the sidewalls of the lower dummy nanostructures 64. Thus, the first lower inner spacers 124A may partially fill, completely fill, or overfill the sidewall recesses. Moreover, although the sidewalls of the first lower inner spacers 124A are illustrated as being straight, the sidewalls of the first lower inner spacers 124A may be concave or convex.

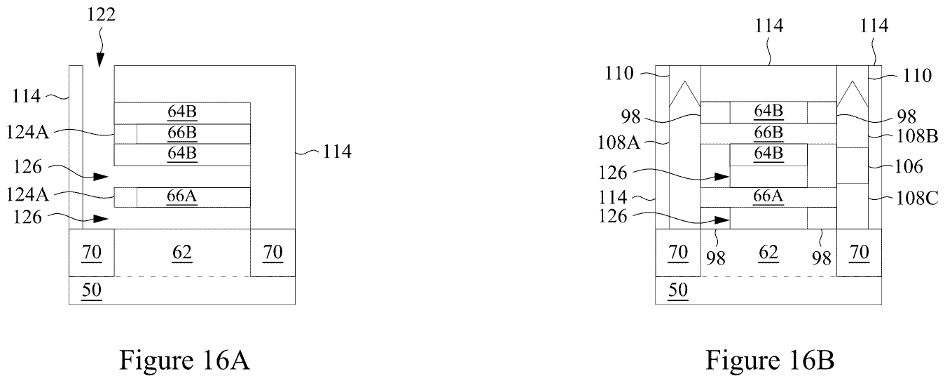

In FIGS. 16A-16B, the remaining portions of the first lower dummy nanostructures 64A are removed to form openings 126 in a region between the first lower semiconductor nanostructure 66A and the semiconductor fin 62 and in a region between the first lower semiconductor nanostructure 66A and the second lower dummy nanostructures 64B. The remaining portions of the first lower dummy nanostructures 64A can be removed by any acceptable etch process that selectively etches the material of the first lower dummy nanostructures 64A at a faster rate than the materials of the lower semiconductor nanostructures 66, the lower inner spacers 98, and the first lower inner spacers 124A. The etching may be isotropic. For example, when the first lower dummy nanostructures 64A are formed of silicon-germanium and the lower semiconductor nanostructures 66 are formed of silicon, the etch process may be a wet etch using tetramethylammonium hydroxide (TMAH), ammonium hydroxide (NH₄OH), or the like.

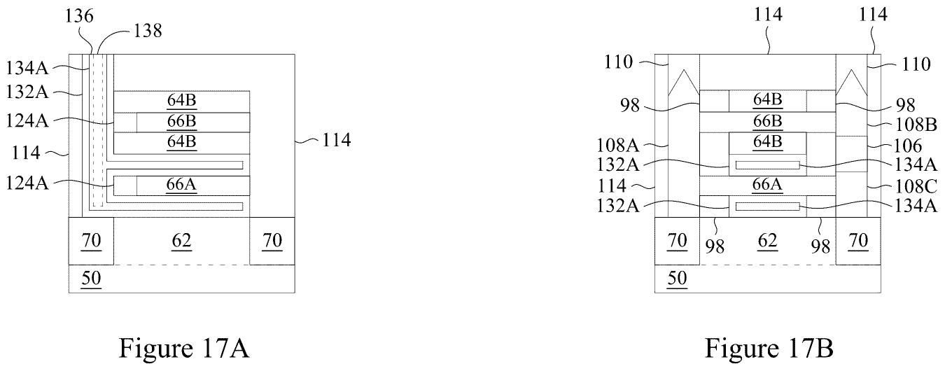

In FIGS. 17A-17B, a first lower gate dielectric 132A and a first lower gate electrode 134A are formed for a replacement gate. The first lower gate dielectric 132A and the first lower gate electrode 134A may be collectively referred to as a “first lower gate structure.” The first lower gate structure extends along a top surface and a bottom surface of the first lower semiconductor nanostructure 66A, and is disposed at a side of the first lower semiconductor nanostructure 66A. Thus, the first lower gate structure is around and controls three surfaces of the first lower semiconductor nanostructure 66A. The first lower gate structure may also extend along a top surface and/or sidewalls of the semiconductor fin 62.

The first lower gate dielectric 132A includes one or more gate dielectric layer(s) disposed on the top surface and the bottom surface of the first lower semiconductor nanostructure 66A; on the top surface of the semiconductor fin 62; on the sidewalls and a bottom surface of the second lower dummy nanostructures 64B; on the sidewalls of the lower inner spacers 98; on the sidewalls of the first lower inner spacers 124A; and on sidewalls of the lower dielectric 114. The first lower gate dielectric 132A may be formed of an oxide such as silicon oxide or a metal oxide, a silicate such as a metal silicate, combinations thereof, multi-layers thereof, or the like. Additionally or alternatively, the first lower gate dielectric 132A may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the first lower gate dielectric 132A may be formed by molecular-beam deposition (MBD), ALD, PECVD, or the like. Although a single-layered first lower gate dielectric 132A is illustrated, the first lower gate dielectric 132A may include any number of interfacial layers and any number of main layers. For example, the first lower gate dielectric 132A may include an interfacial layer and an overlying high-k dielectric layer.

The first lower gate electrode 134A includes one or more gate electrode layer(s) disposed over the first lower gate dielectric 132A and around three sides of the first lower semiconductor nanostructure 66A. The first lower gate electrode 134A may be formed of a metal-containing material such as tungsten, titanium, titanium nitride, tantalum, tantalum nitride, tantalum carbide, aluminum, ruthenium, cobalt, combinations thereof, multi-layers thereof, or the like. The first lower gate electrode 134A may include any number of work function tuning layers, any number of barrier layers, any number of glue layers, and a fill material. For example, the first lower gate electrode 134A may include a work function tuning layer 136 (of, e.g., titanium nitride) and a fill material 138 (of, e.g., tungsten), where the work function tuning layer 136 completely fills the portions of the openings 126 not filled by the first lower gate dielectric 132A, while the fill material 138 is disposed in the recess 122 but not the openings 126.

As an example to form the first lower gate structure, one or more gate dielectric layer(s) may be deposited in the recess 122 and the openings 126. The gate dielectric layer(s) may also be deposited on the top surfaces of the lower source/drain contacts 110 and the lower dielectric 114. Subsequently, one or more gate electrode layer(s) may be deposited on the gate dielectric layer(s), and in the remaining portions of the recess 122 and the openings 126. A removal process is performed to remove the excess portions of the gate dielectric layer(s) and the gate electrode layer(s), which excess portions are over the top surfaces of the lower source/drain contacts 110 and the lower dielectric 114. In some embodiments, a planarization process such as a chemical mechanical polish (CMP), an etch-back process, combinations thereof, or the like may be utilized. The gate dielectric layer(s), after the removal process, have portions remaining in the recess 122 and the openings 126 (thus forming the first lower gate dielectric 132A). The gate electrode layer(s), after the removal process, have portions remaining in the recess 122 and the openings 126 (thus forming the first lower gate electrode 134A). When a planarization process is utilized, the top surfaces of the first lower gate electrode 134A, the first lower gate dielectric 132A, the lower source/drain contacts 110, and the lower dielectric 114 are substantially coplanar (within process variations).

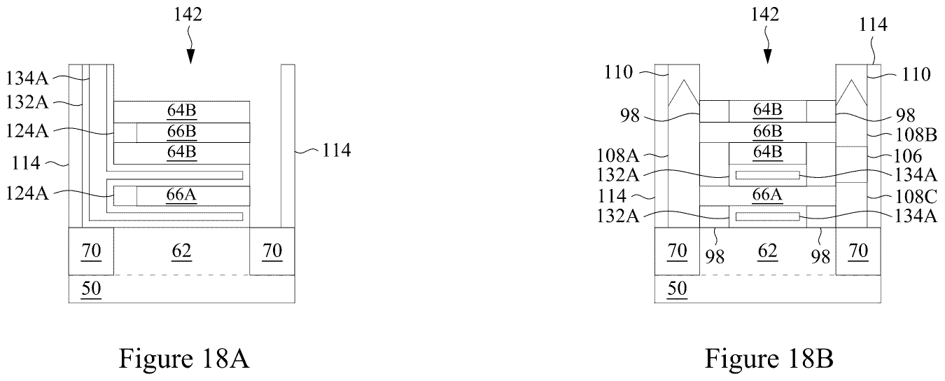

In FIGS. 18A-18B, a recess 142 is formed in the lower dielectric 114 to expose the second sidewalls of the lower nanostructures 64, 66. The second sidewalls are at a second side of the lower nanostructures 64, 66 in the cross-section of FIG. 18A. The second sidewalls of the lower nanostructures 64, 66 are opposite the first lower inner spacers 124A. The recess 142 may be formed using an etching process, such as one that is selective to the lower dielectric 114 (e.g., selectively etches the dielectric material of the lower dielectric 114 at a faster rate than the materials of the lower nanostructures 64, 66). The recess 142 also exposes a top surface of the second lower dummy nanostructures 64B, the top surfaces of the lower inner spacers 98, and the sidewalls of the lower source/drain contacts 110.

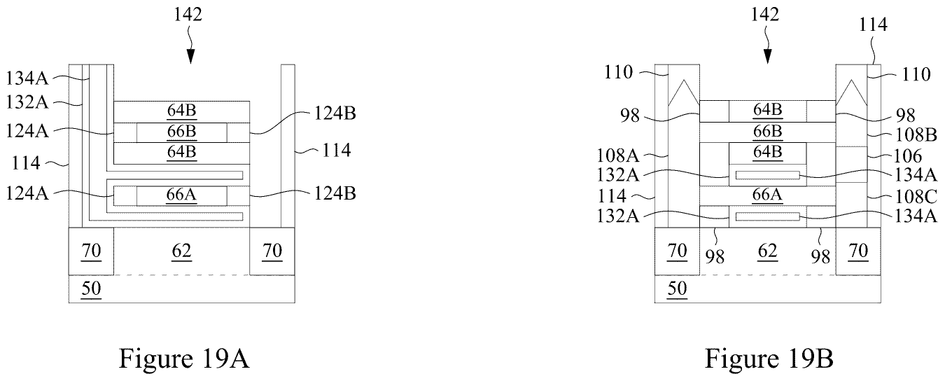

In FIGS. 19A-19B, second lower inner spacers 124B are formed on the sidewalls of the lower semiconductor nanostructures 66. As subsequently described in greater detail, a second lower gate structure will be formed around the second lower semiconductor nanostructure 66B. The second lower inner spacers 124B act as isolation features between the subsequently formed second lower gate structure and the first lower semiconductor nanostructure 66A. The second lower inner spacers 124B may be formed of similar material(s) as the first lower inner spacers 124A, and may be formed by similar process(es) as those used to form the first lower inner spacers 124A (previously described for FIGS. 15A-15B).

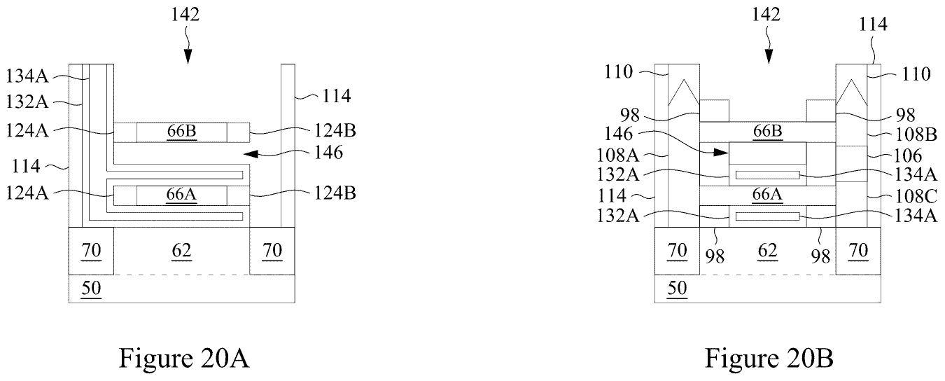

In FIGS. 20A-20B, the remaining portions of the second lower dummy nanostructures 64B are removed to form an opening 146 in a region between the second lower semiconductor nanostructure 66B and the first lower gate electrode 134A. The remaining portions of the second lower dummy nanostructures 64B may be removed by a similar process as that used to remove the first lower dummy nanostructures 64A (previously described for FIGS. 16A-16B).

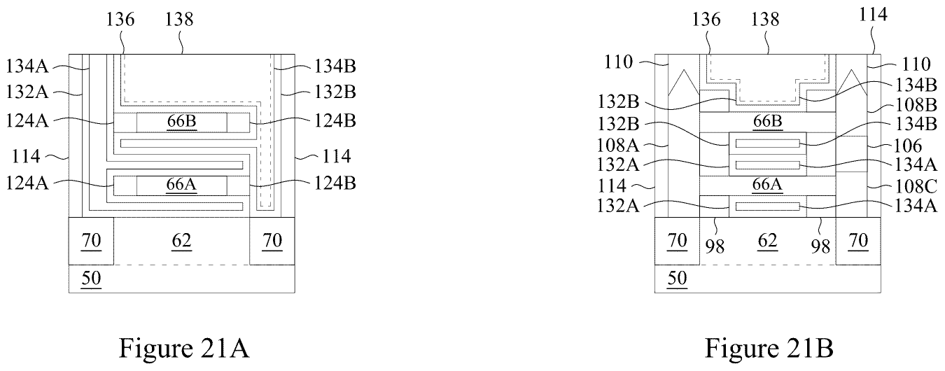

In FIGS. 21A-21B, a second lower gate dielectric 132B and a second lower gate electrode 134B are formed for a replacement gate. The second lower gate dielectric 132B and the second lower gate electrode 134B may be collectively referred to as a “second lower gate structure.” The second lower gate structure extends along a top surface and a bottom surface of the second lower semiconductor nanostructure 66B, and is disposed at a side of the second lower semiconductor nanostructure 66B. Thus, the second lower gate structure is around and controls three surfaces of the second lower semiconductor nanostructure 66B.

The second lower gate dielectric 132B includes one or more gate dielectric layer(s) disposed on the top surface and the bottom surface of the second lower semiconductor nanostructure 66B; on the sidewalls of the lower inner spacers 98; on the sidewalls of the second lower inner spacers 124B; on sidewalls of the lower dielectric 114; and on sidewalls of the lower source/drain contacts 110. The second lower gate dielectric 132B may be formed of similar material(s) as the first lower gate dielectric 132A, and may be formed by similar process(es) as those used to form the first lower gate dielectric 132A (previously described for FIGS. 17A-17B). The first lower gate dielectric 132A and the second lower gate dielectric 132B may further be collectively referred to as the lower gate dielectrics 132.

The second lower gate electrode 134B includes one or more gate electrode layer(s) disposed over the second lower gate dielectric 132B and around three sides of the second lower semiconductor nanostructure 66B. The second lower gate electrode 134B may be formed of similar material(s) as the first lower gate electrode 134A, and may be formed by similar process(es) as those used to form the first lower gate electrode 134A (previously described for FIGS. 17A-17B). For example, the second lower gate electrode 134B may include a work function tuning layer 136 (of, e.g., titanium nitride) and a fill material 138 (of, e.g., tungsten), where the work function tuning layer 136 completely fills the portion of the opening 146 not filled by the second lower gate dielectric 132B, while the fill material 138 is disposed in the recess 142 but not the opening 146. The first lower gate electrode 134A and the second lower gate electrode 134B may further be collectively referred to as the lower gate electrodes 134.

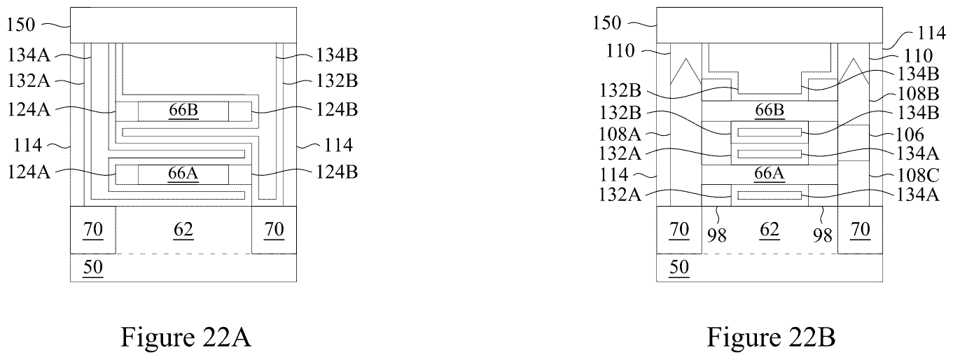

In FIGS. 22A-22B, an isolation dielectric 150 is formed on the lower source/drain contacts 110, the lower dielectric 114, the lower gate dielectrics 132, and the lower gate electrodes 134. The isolation dielectric 150 may be formed by conformally forming a dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used.

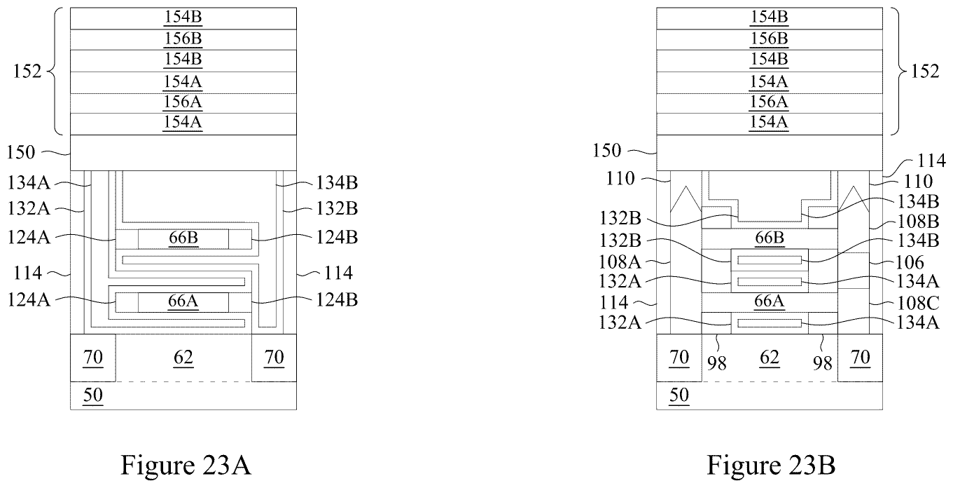

In FIGS. 23A-23B, an upper multi-layer stack 152 is formed over the isolation dielectric 150. The upper multi-layer stack 152 includes upper dummy layers 154 (including first upper dummy layers 154A and second upper dummy layers 154B) and upper semiconductor layers 156 (including a first upper semiconductor layer 156A and a second upper semiconductor layer 156B). The first upper semiconductor layer 156A is between the first upper dummy layers 154A. The second upper semiconductor layer 156B is between the second upper dummy layers 154B. As subsequently described in greater detail, the upper dummy layers 154 will be removed and the upper semiconductor layers 156 will be patterned to form channel regions of stacked transistors. Specifically, the first upper semiconductor layer 156A will be patterned to form a first channel region of a first upper nanostructure-FET of the stacked transistors, and the second upper semiconductor layer 156B will be patterned to form a second channel region of a second upper nanostructure-FET of the stacked transistors. The upper multi-layer stack 152 may be formed of similar material(s) as the lower multi-layer stack 52, and may be formed by similar process(es) as those used to form the lower multi-layer stack 52 (previously described for FIGS. 2A-2B). The conductivity type of the upper semiconductor layers 156 is opposite the conductivity type of the lower semiconductor layers 56. In some embodiments, the lower semiconductor layers 56 are formed of a semiconductor material suitable for n-type devices, while the upper semiconductor layers 156 are formed of a semiconductor material suitable for p-type devices.

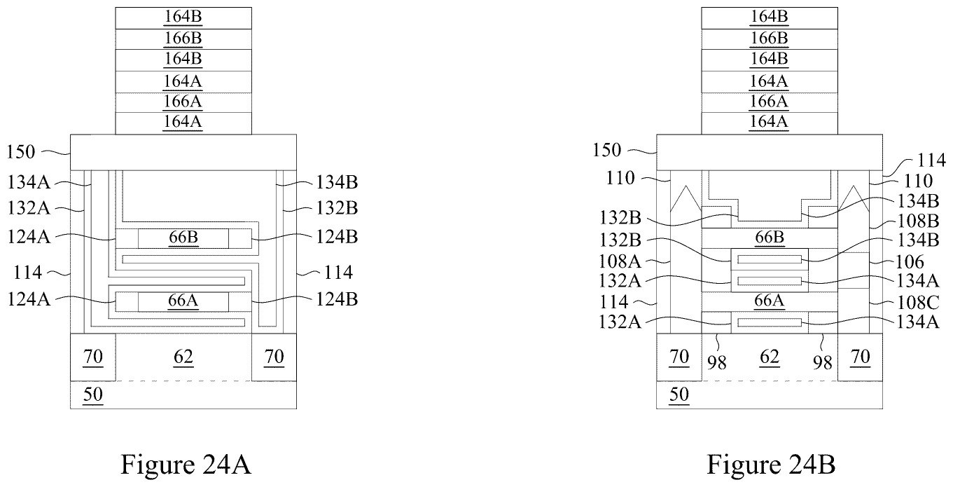

In FIGS. 24A-24B, upper nanostructures 164, 166 (including first upper dummy nanostructures 164A, second upper dummy nanostructures 164B, a first upper semiconductor nanostructure 166A, and a second upper semiconductor nanostructure 166B) are formed in the upper multi-layer stack 152. In some embodiments, the upper nanostructures 164, 166 may be formed in the upper multi-layer stack 152 by etching trenches in the upper multi-layer stack 152. The upper multi-layer stack 152 may be patterned by a similar process as that used to pattern the lower multi-layer stack 52 (previously described for FIGS. 3A-3B). The first upper dummy nanostructures 164A and the second upper dummy nanostructures 164B may further be collectively referred to as the upper dummy nanostructures 164. The first upper semiconductor nanostructure 166A and the second upper semiconductor nanostructure 166B may further be collectively referred to as the upper semiconductor nanostructures 166.

The vertical distance between the first upper dummy nanostructure 164A and the second upper dummy nanostructure 164B may (or may not) be different than the vertical distance between the first lower dummy nanostructure 64A and the second lower dummy nanostructure 64B. In some embodiments, the vertical distance between the first lower dummy nanostructure 64A and the second lower dummy nanostructure 64B is in the range of 3 nm to 200 nm. In some embodiments, the vertical distance between the first upper dummy nanostructure 164A and the second upper dummy nanostructure 164B is in the range of 3 nm to 200 nm.

As subsequently described in greater detail, various one of the upper nanostructures 164, 166 will be removed to form channel regions of stacked transistors. Specifically, the first upper semiconductor nanostructure 166A will act as a channel region for a first upper nanostructure-FET of the stacked transistors. Additionally, the second upper semiconductor nanostructure 166B will act as a channel region for a second upper nanostructure-FET of the stacked transistors.

Further, appropriate wells (not separately illustrated) may be formed in the upper semiconductor nanostructures 166. The wells may be formed in the upper semiconductor nanostructures 166 by a similar process as that used to form the wells in the lower semiconductor nanostructures 66 (previously described for FIGS. 4A-4B). The wells in the upper semiconductor nanostructures 166 have a conductivity type opposite from a conductivity type of lower source/drain regions that will be subsequently formed adjacent the upper semiconductor nanostructures 166.

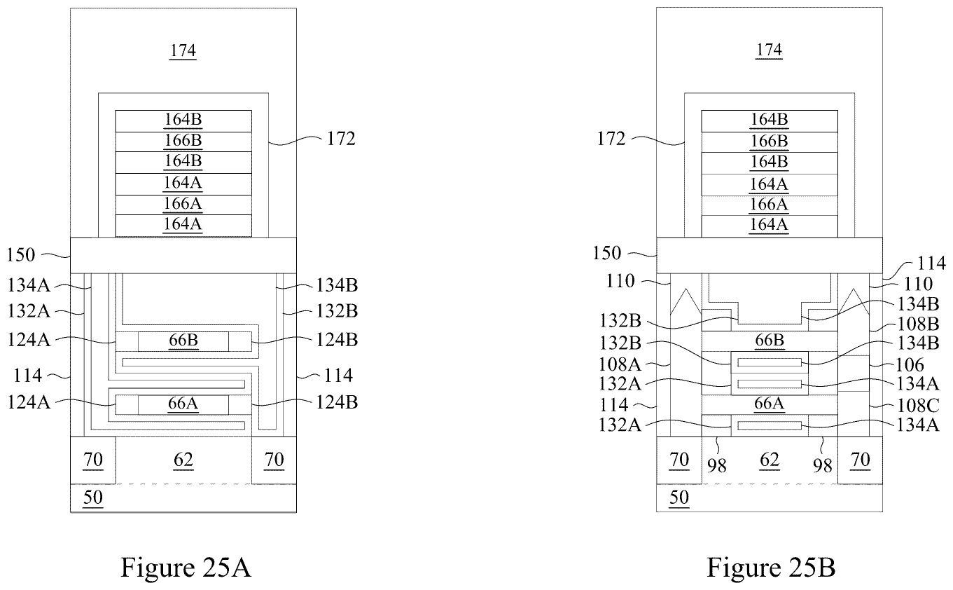

In FIGS. 25A-25B, an upper dummy dielectric layer 172 is formed on the upper nanostructures 164, 166. The upper dummy dielectric layer 172 may be formed of similar material(s) as the lower dummy dielectric layer 72, and may be formed by similar process(es) as those used to form the lower dummy dielectric layer 72 (previously described for FIGS. 5A-5B). An upper dummy gate layer 174 is formed over the upper dummy dielectric layer 172. The upper dummy gate layer 174 may be formed of similar material(s) as the lower dummy gate layer 74, and may be formed by similar process(es) as those used to form the lower dummy gate layer 74 (previously described for FIGS. 5A-5B).

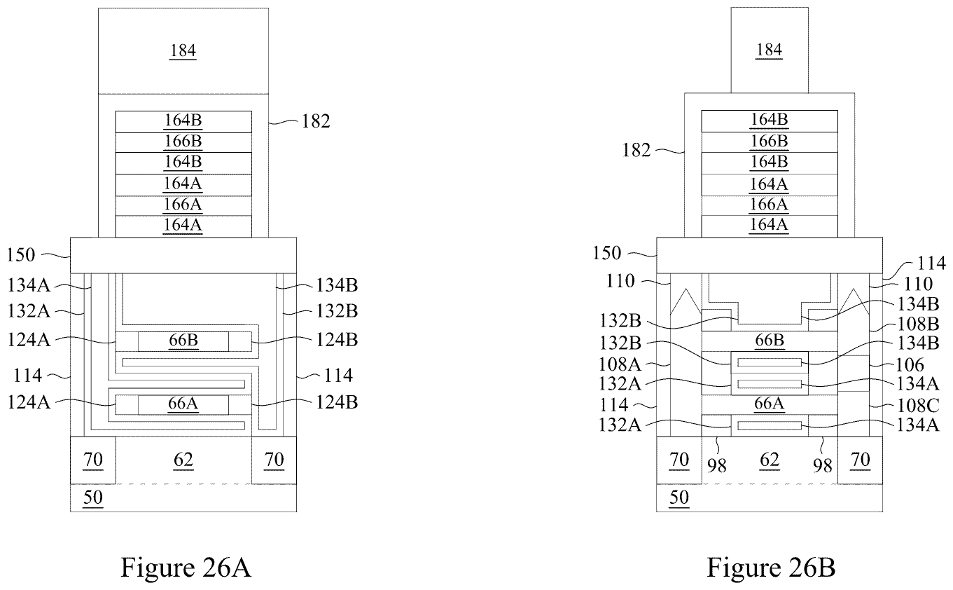

In FIGS. 26A-26B, the upper dummy gate layer 174 is patterned to form an upper dummy gate 184. The upper dummy gate layer 174 may be patterned by a similar process as that used to pattern the lower dummy gate layer 74 (previously described for FIGS. 6A-6B). Additionally, the upper dummy dielectric layer 172 is patterned to form an upper dummy dielectric 182. The upper dummy dielectric layer 172 may be patterned by a similar process as that used to pattern the lower dummy dielectric layer 72 (previously described for FIGS. 6A-6B).

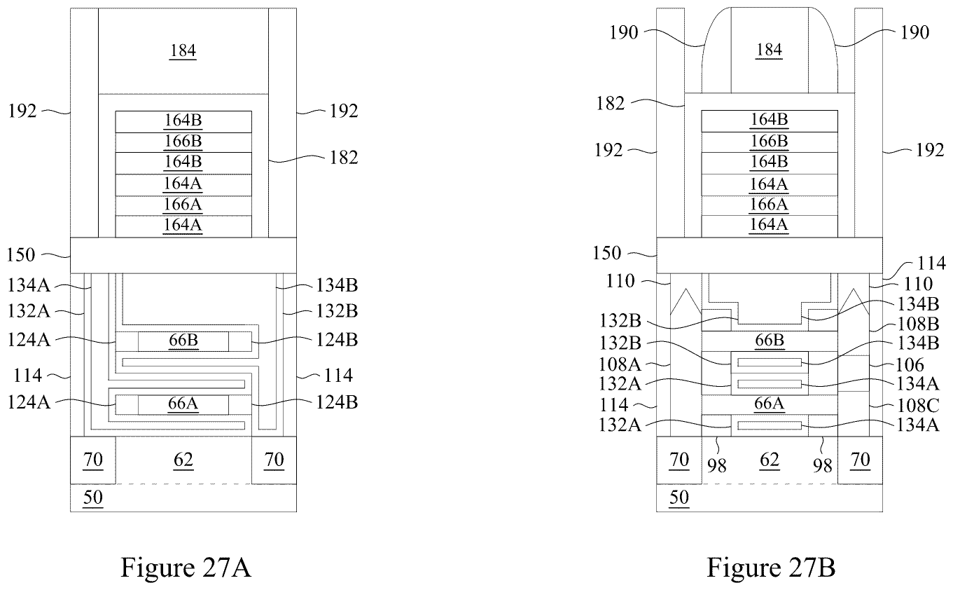

In FIGS. 27A-27B, upper gate spacers 190 are formed over the upper nanostructures 164, 166 and on exposed sidewalls of the upper dummy gate 184. The upper gate spacers 190 may be formed of similar material(s) as the lower gate spacers 90, and may be formed by similar process(es) as those used to form the lower gate spacers 90 (previously described for FIGS. 7A-7B).

Further, implants for lightly doped source/drain (LDD) regions (not separately illustrated) may be performed. The LDD implants may be performed in the upper semiconductor nanostructures 166 by a similar process as that used to perform the LDD implants in the lower semiconductor nanostructures 66 (previously described for FIGS. 7A-7B).

An upper mask 192 may be formed over the isolation dielectric 150 and around the upper nanostructures 164, 166 (e.g., on the sidewalls of the upper dummy dielectric 182 and the upper dummy gate 184 in the cross-section of FIG. 27A). The upper mask 192 may be formed of similar material(s) as the lower mask 92, and may be formed by similar process(es) as those used to form the lower mask 92 (previously described for FIGS. 7A-7B).

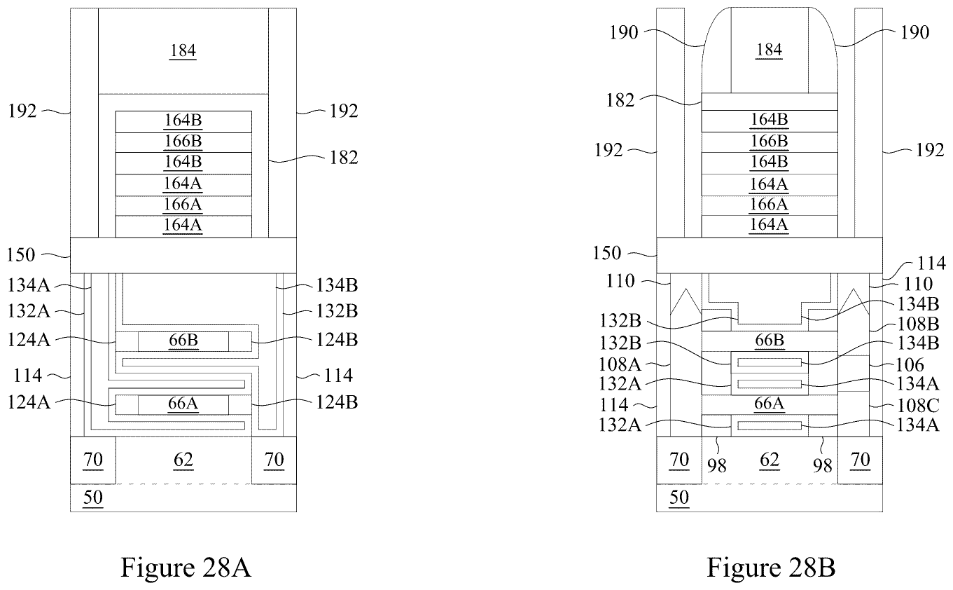

In FIGS. 28A-28B, the upper dummy dielectric 182 is patterned to expose the sidewalls of the upper nanostructures 164, 166 in the cross-section of FIG. 28B. The upper dummy dielectric 182 may be patterned by a similar process as that used to pattern the lower dummy dielectric 82 (previously described for FIGS. 8A-8B), e.g., using the upper mask 192 and the upper gate spacers 190 as an etching mask.

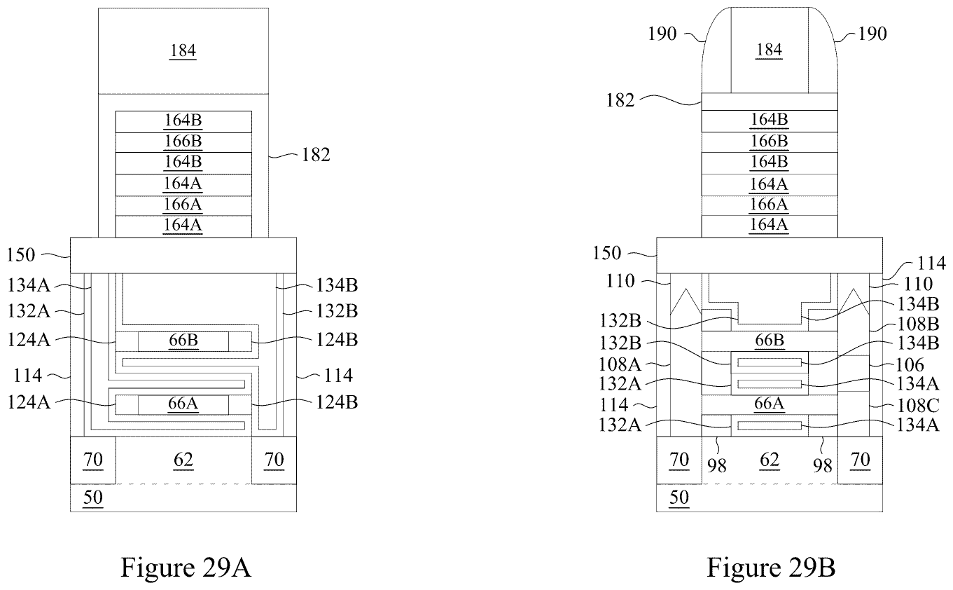

In FIGS. 29A-29B, the upper mask 192 is removed to expose the isolation dielectric 150. The upper mask 192 may be removed by a similar process as that used to remove the lower mask 92 (previously described for FIGS. 9A-9B).

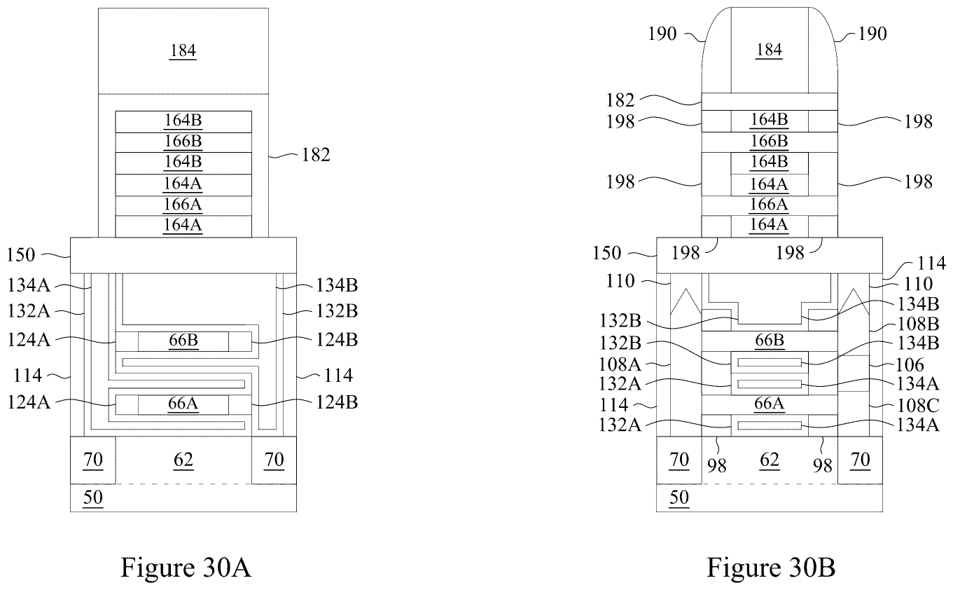

In FIGS. 30A-30B, upper inner spacers 198 are formed on the sidewalls of the upper dummy nanostructures 164. The upper inner spacers 198 may be formed of similar material(s) as the lower inner spacers 98, and may be formed by similar process(es) as those used to form the lower inner spacers 98 (previously described for FIGS. 10A-10B).

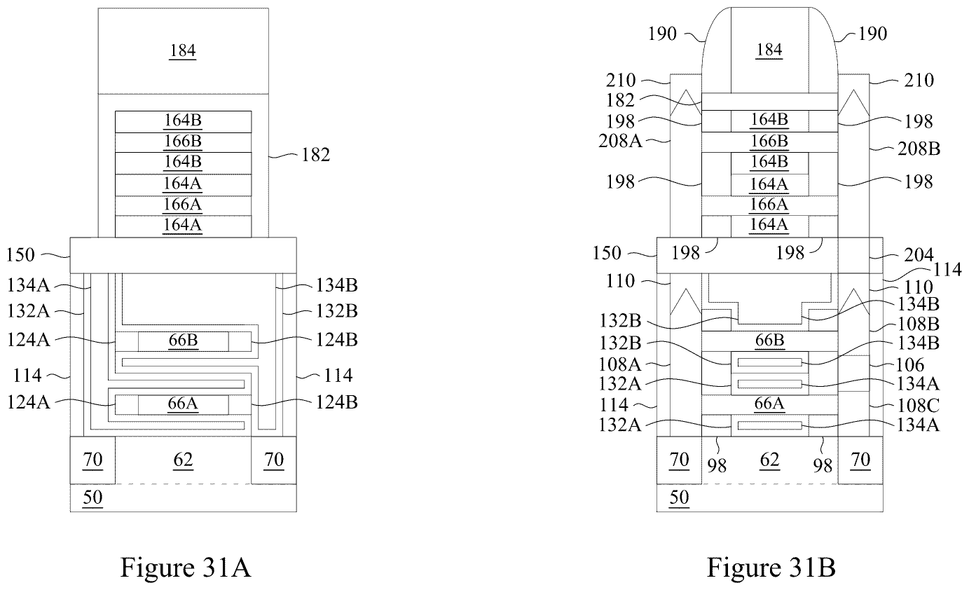

In FIGS. 31A-31B, upper epitaxial source/drain regions 208 are formed on the sidewalls of the upper semiconductor nanostructures 166. The upper dummy dielectric 182 masks the upper semiconductor nanostructures 166 in the cross-section of FIG. 31A, so that the upper epitaxial source/drain regions 208 are on the sidewalls of the upper semiconductor nanostructures 166 in the cross-section of FIG. 31B. In some embodiments, the upper epitaxial source/drain regions 208 exert stress in the respective channel regions of the upper semiconductor nanostructures 166, thereby improving performance. The upper epitaxial source/drain regions 208 are formed such that the upper semiconductor nanostructures 166 are disposed between the upper epitaxial source/drain regions 208. In some embodiments, the upper inner spacers 198 are used to separate the upper epitaxial source/drain regions 208 from the upper dummy nanostructures 164 by an appropriate lateral distance so that the upper epitaxial source/drain regions 208 do not short out with subsequently formed gates of the resulting devices.

The upper epitaxial source/drain regions 208 may be formed of similar material(s) as the lower epitaxial source/drain regions 108, and may be formed by similar process(es) as those used to form the lower epitaxial source/drain regions 108 (previously described for FIGS. 11A-11B). The conductivity type of the upper epitaxial source/drain regions 208 is opposite the conductivity type of the lower epitaxial source/drain regions 108. In some embodiments, the lower epitaxial source/drain regions 108 are n-type source/drain regions, while the upper epitaxial source/drain regions 208 are p-type source/drain regions.

As a result of the epitaxy processes used to form the upper epitaxial source/drain regions 208, upper surfaces of the upper epitaxial source/drain regions 208 have facets which expand laterally outward beyond sidewalls of the upper nanostructures 164, 166. In some embodiments, adjacent upper epitaxial source/drain regions 208 remain separated after the epitaxy process is completed. In other embodiments, these facets cause adjacent upper epitaxial source/drain regions 208 of a same nanostructure-FET to merge (not separately illustrated). The growth of the upper epitaxial source/drain regions 208 may extend to the surface of the isolation dielectric 150.

In this embodiment, the upper epitaxial source/drain regions 208 include a first upper epitaxial source/drain region 208A and a second upper epitaxial source/drain region 208B. The first upper epitaxial source/drain region 208A is on the sidewalls of both the first upper semiconductor nanostructure 166A and the second upper semiconductor nanostructure 166B. The second upper epitaxial source/drain region 208B is on the sidewalls of both the first upper semiconductor nanostructure 166A and the second upper semiconductor nanostructure 166B, opposite the first upper epitaxial source/drain region 208A. Thus, the first upper epitaxial source/drain region 208A and the second upper epitaxial source/drain region 208B will each be shared between a first upper nanostructure-FET and a second upper nanostructure-FET.

A lower source/drain via 204 may be formed through the isolation dielectric 150. The lower source/drain via 204 connects a lower epitaxial source/drain region 108 to an upper epitaxial source/drain region 208. In this embodiment, the lower source/drain via 204 connects the second upper epitaxial source/drain region 208B to the second lower epitaxial source/drain region 108B. The lower source/drain via 204 may be formed of a conductive material and by a suitable damascene process, such as a single damascene process. The conductive material may be cobalt, tungsten, copper, a copper alloy, silver, gold, aluminum, nickel, or the like.

Further, upper source/drain contacts 210 are formed for the upper epitaxial source/drain regions 208. The upper source/drain contacts 210 may be physically and electrically coupled to the upper epitaxial source/drain regions 208 or to the lower source/drain contacts 110. The upper source/drain contacts 210 to the upper epitaxial source/drain regions 208 (shown in FIG. 31B) may be formed in different cross-sections than the upper source/drain contacts 210 to the lower source/drain contacts 110 (not separately illustrated). The upper source/drain contacts 210 may be formed of similar material(s) as the lower source/drain contacts 110, and may be formed by similar process(es) as those used to form the lower source/drain contacts 110 (previously described for FIGS. 11A-11B).

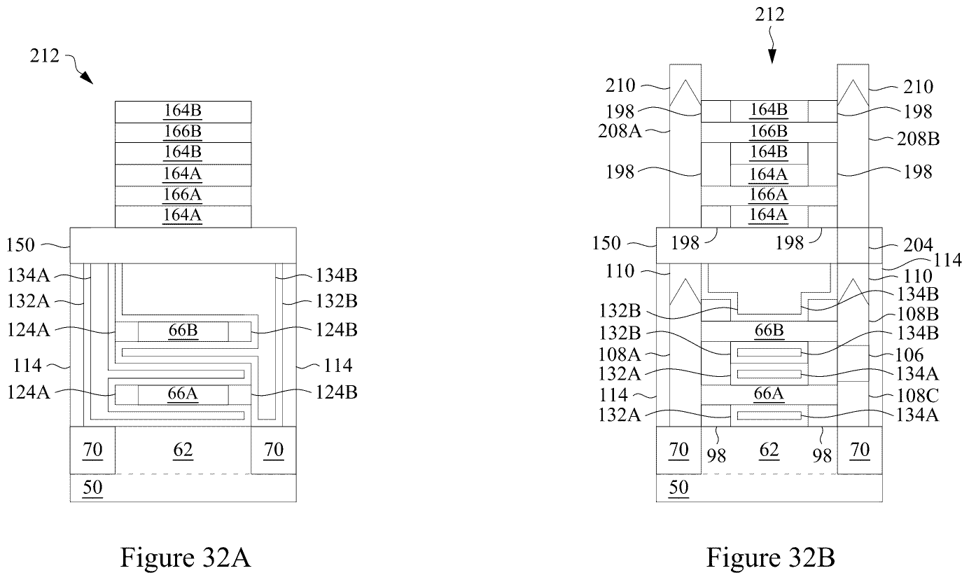

In FIGS. 32A-32B, the upper dummy gate 184 is removed in one or more etching steps, so that a recess 212 is formed between the upper epitaxial source/drain regions 208. Portions of the upper dummy dielectric 182 in the recess 212 are also removed. The upper dummy gate 184 and the upper dummy dielectric 182 may be removed by similar process(es) as those used to remove the lower dummy gate 84 and the lower dummy dielectric 82 (previously described for FIGS. 12A-12B). Optionally, the upper gate spacers 190 may also be removed during the formation of the recess 212.

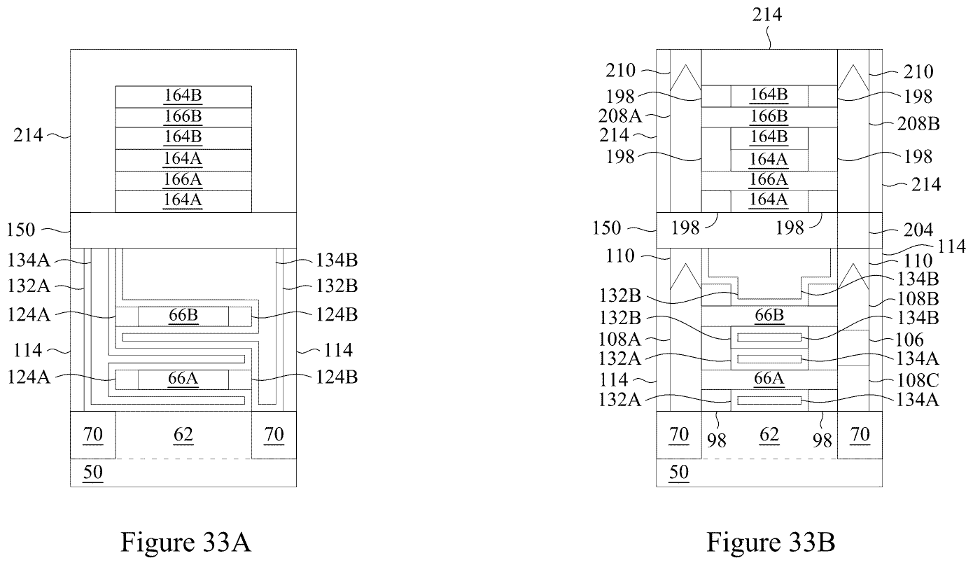

In FIGS. 33A-33B, an upper dielectric 214 is formed in the recess 212, such as over the upper nanostructures 164, 166. The upper dielectric 214 may also be formed around the upper epitaxial source/drain regions 208. The upper dielectric 214 may be formed of similar material(s) as the lower dielectric 114, and may be formed by similar process(es) as those used to form the lower dielectric 114 (previously described for FIGS. 13A-13B). A removal process is performed to level the top surfaces of the upper dielectric 214 with the top surfaces of the upper source/drain contacts 210. In some embodiments, a planarization process such as a chemical mechanical polish (CMP), an etch-back process, combinations thereof, or the like may be utilized. After the planarization process, top surfaces of the upper dielectric 214 and the upper source/drain contacts 210 are substantially coplanar (within process variations). The upper dielectric 214 covers the upper nanostructures 164, 166.

As subsequently described in greater detail, a first upper gate structure will be formed around the first upper semiconductor nanostructure 166A, while a second upper gate structure will be formed around the second upper semiconductor nanostructure 166B. The first upper gate structure and the second upper gate structure will be disposed at opposing sides of the upper semiconductor nanostructures 166. The first upper gate structure is for a first upper nanostructure-FET while the second upper gate structure is for a second upper nanostructure-FET. The second upper nanostructure-FET will be stacked over the first upper nanostructure-FET.

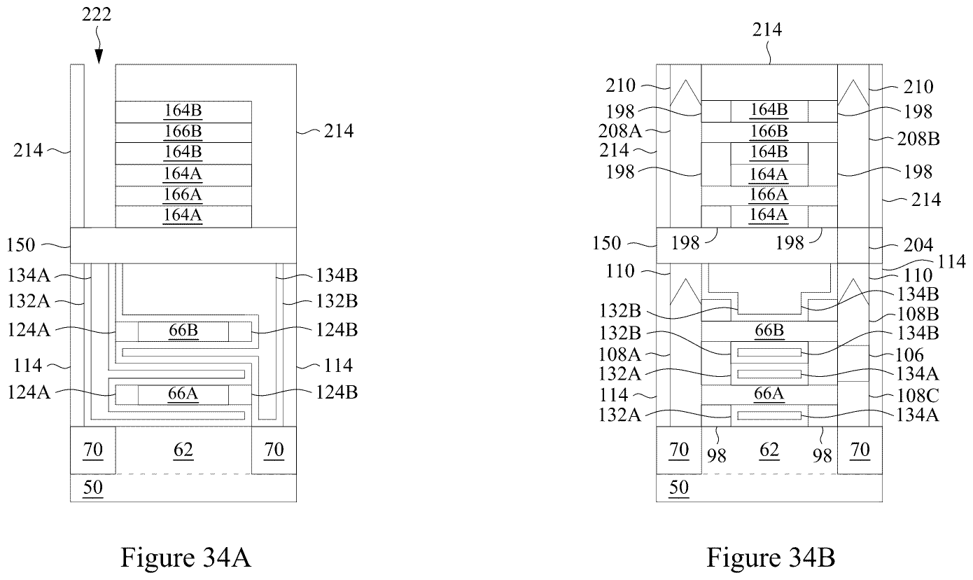

In FIGS. 34A-34B, a recess 222 is formed in the upper dielectric 214 to expose first sidewalls of the upper nanostructures 164, 166. The first sidewalls are at a first side of the upper nanostructures 164, 166 in the cross-section of FIG. 34A. Second sidewalls of the upper nanostructures 164, 166 opposite the first sidewalls remain covered by the upper dielectric 214 at this step. The recess 222 may be formed by a similar process as that used to form the recess 122 (previously described for FIGS. 14A-14B).

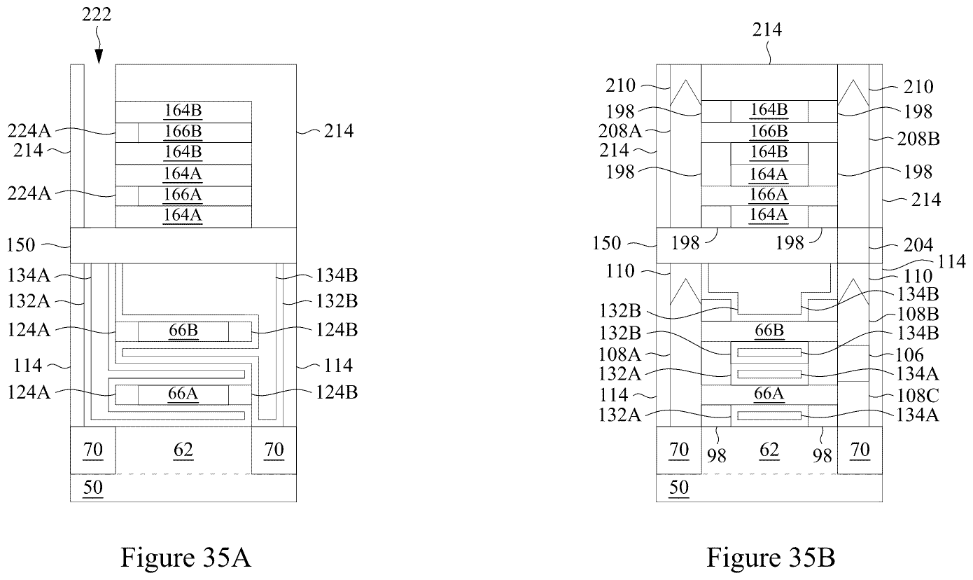

In FIGS. 35A-35B, first upper inner spacers 224A are formed on the sidewalls of the upper semiconductor nanostructures 166. As subsequently described in greater detail, a first upper gate structure will be formed around the first upper semiconductor nanostructure 166A. The first upper inner spacers 224A act as isolation features between the subsequently formed first upper gate structure and the second upper semiconductor nanostructure 166B. The first upper inner spacers 224A may be formed of similar material(s) as the first lower inner spacers 124A, and may be formed by similar process(es) as those used to form the first lower inner spacers 124A (previously described for FIGS. 15A-15B).

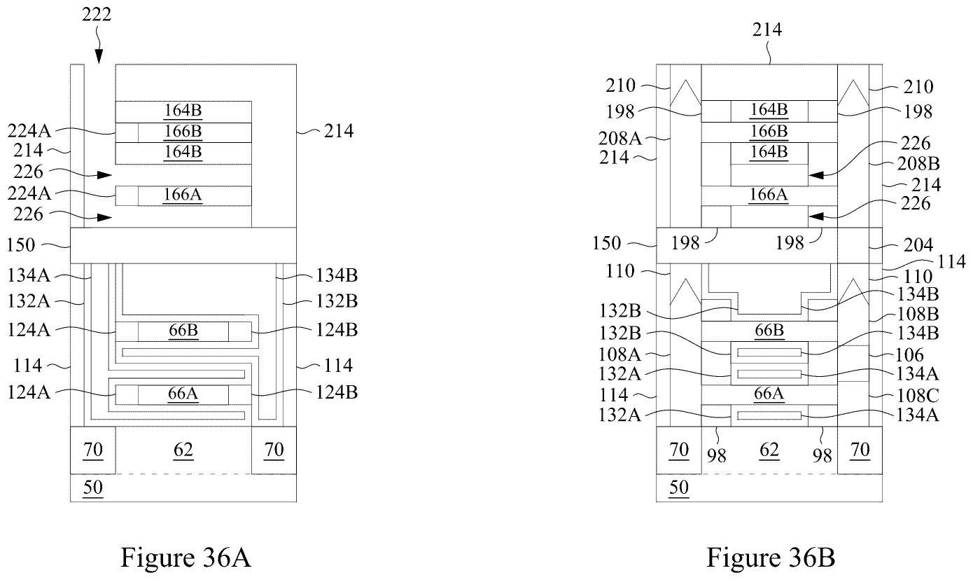

In FIGS. 36A-36B, the remaining portions of the first upper dummy nanostructures 164A are removed to form openings 226 in a region between the first upper semiconductor nanostructure 166A and the isolation dielectric 150 and in a region between the first upper semiconductor nanostructure 166A and the second upper dummy nanostructures 164B. The remaining portions of the first upper dummy nanostructures 164A can be removed by a similar process as that used to remove the first lower dummy nanostructures 64A (previously described for FIGS. 16A-16B).

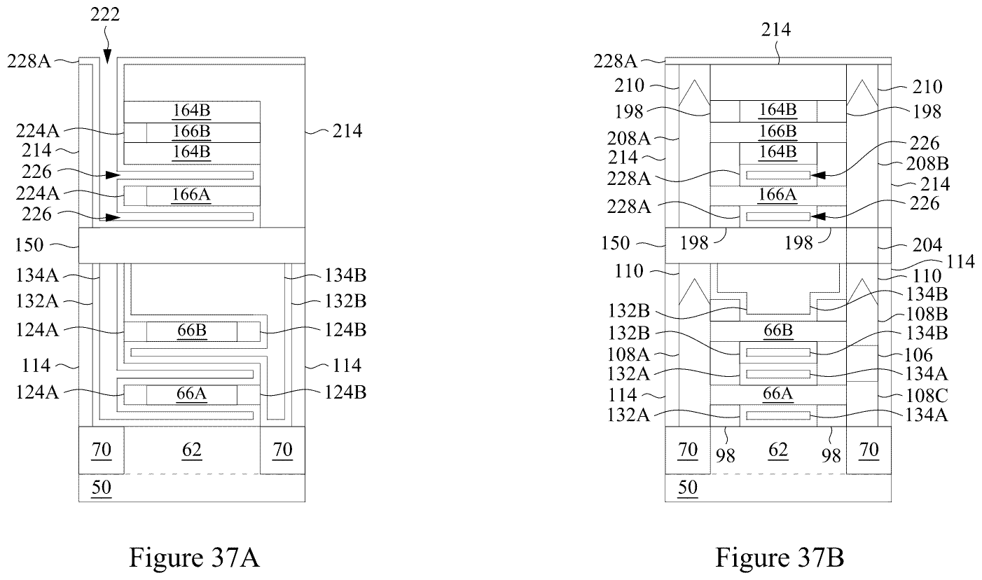

In FIGS. 37A-37B, one or more first gate dielectric layer(s) 228A are formed in the recess 222 and in the openings 226, as well as on the upper dielectric 214. The first gate dielectric layer(s) 228A are disposed on the top surface and the bottom surface of the first upper semiconductor nanostructure 166A; on the top surface of the isolation dielectric 150; on the sidewalls and a bottom surface of the second upper dummy nanostructures 164B; on the sidewalls of the upper inner spacers 198; on the sidewalls of the first upper inner spacers 224A; and on sidewalls and a top surface of the upper dielectric 214. The first gate dielectric layer(s) 228A may be formed of similar material(s) as the first lower gate dielectric 132A, and may be formed by similar process(es) as those used to form the material(s) of the first lower gate dielectric 132A (previously described for FIGS. 17A-17B).

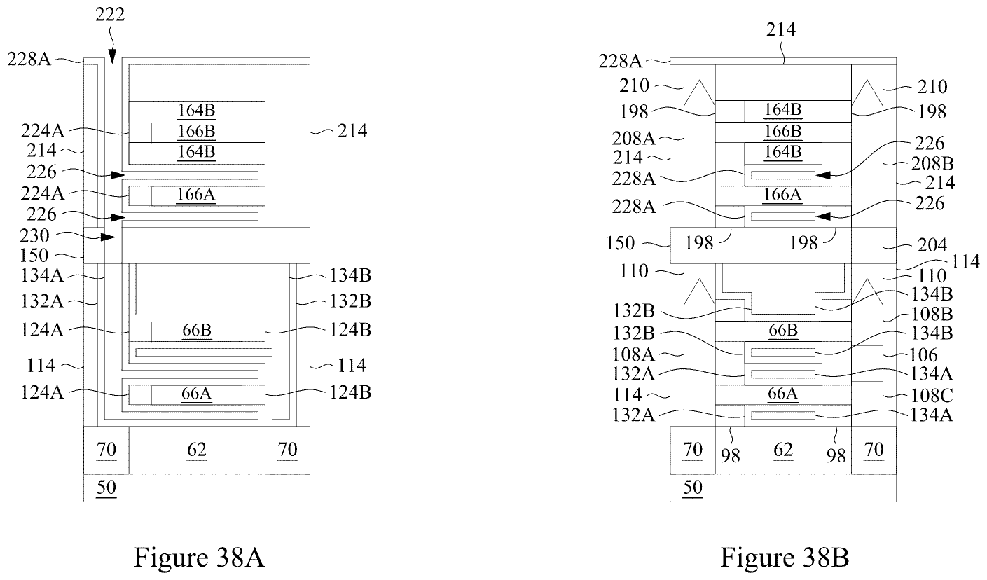

In FIGS. 38A-38B, an opening 230 is patterned in the first gate dielectric layer(s) 228A and the isolation dielectric 150, at the bottom of the recess 222. The opening 230 may be patterned using acceptable photolithography and etching techniques. The opening 230 exposes the first lower gate electrode 134A. The opening 230 is aligned with the recess 222.

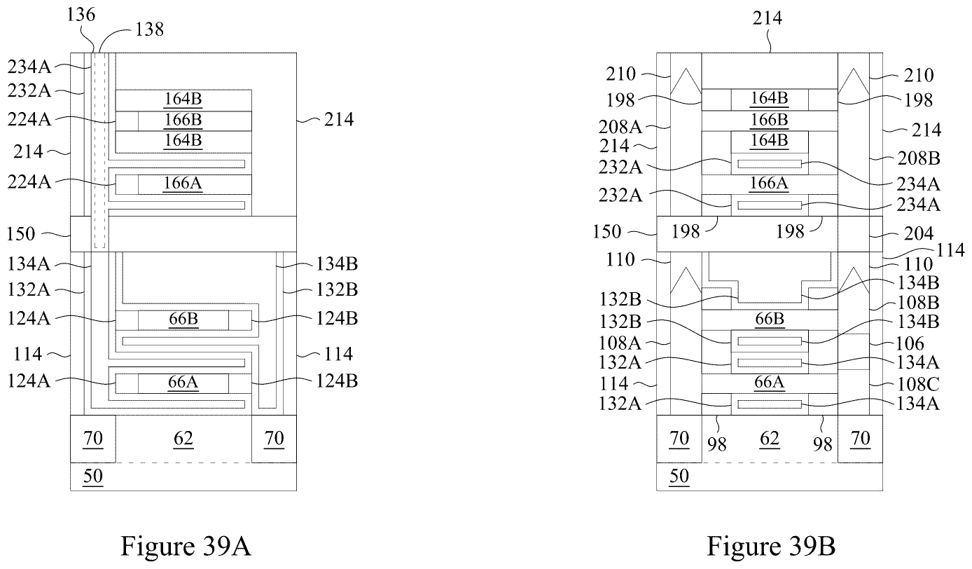

In FIGS. 39A-39B, a first upper gate electrode 234A is formed over the first gate dielectric layer(s) 228A and in the opening 230. The first upper gate electrode 234A may be formed of similar material(s) as the first lower gate electrode 134A, and may be formed by similar process(es) as those used to form the first lower gate electrode 134A (previously described for FIGS. 17A-17B). Additionally, a removal process is applied to the first gate dielectric layer(s) 228A to form a first upper gate dielectric 232A from portions of the first gate dielectric layer(s) 228A remaining in the recess 222 and the openings 226. The removal process may be performed when forming the first upper gate electrode 234A. The first upper gate electrode 234A may include a work function tuning layer 136 (of, e.g., titanium nitride) and a fill material 138 (of, e.g., tungsten), where the work function tuning layer 136 completely fills the portion of the openings 226 not filled by the first upper gate dielectric 232A, while the fill material 138 is disposed in the recess 222 and the opening 230 but in not the opening 226. The work function tuning layer 136 of the first upper gate electrode 234A is disposed between the fill material 138 of the first upper gate electrode 234A and the fill material of the first lower gate electrode 134A.

The first upper gate dielectric 232A and the first upper gate electrode 234A may be collectively referred to as a “first upper gate structure.” The first upper gate structure extends along a top surface and a bottom surface of the first upper semiconductor nanostructure 166A, and is disposed at a side of the first upper semiconductor nanostructure 166A. Thus, the first upper gate structure is around and controls three surfaces of the first upper semiconductor nanostructure 166A.

The first upper gate electrode 234A extends through the opening 230 in the isolation dielectric 150. Thus, the first upper gate electrode 234A contacts the first lower gate electrode 134A. Accordingly, the first lower gate electrode 134A and the first upper gate electrode 234A may be controlled together.

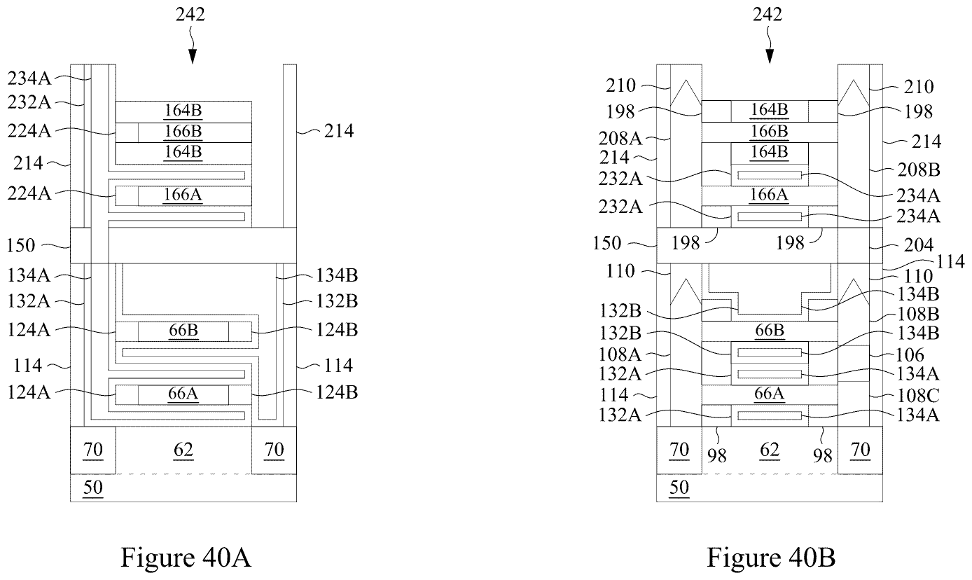

In FIGS. 40A-40B, a recess 242 is formed in the upper dielectric 214 to expose the second sidewalls of the upper nanostructures 164, 166. The second sidewalls are at a second side of the upper nanostructures 164, 166 in the cross-section of FIG. 40A. The second sidewalls of the upper nanostructures 164, 166 are opposite the first upper inner spacers 224A. The recess 242 may be formed by a similar process as that used to form the recess 142 in the lower dielectric 114 (previously described for FIGS. 18A-18B). The recess 242 also exposes a top surface of the second upper dummy nanostructures 164B, the top surfaces of the upper inner spacers 198, and the sidewalls of the upper source/drain contacts 210.

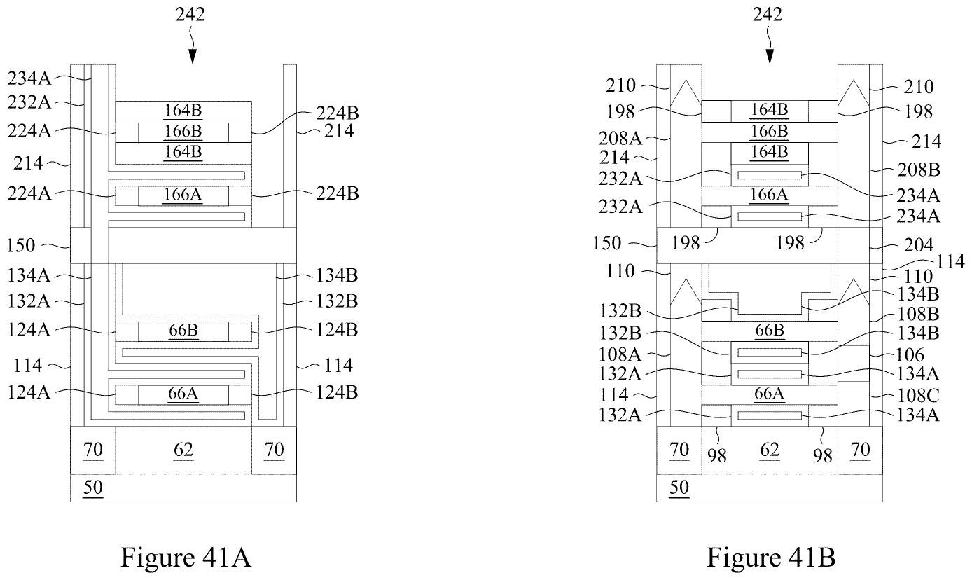

In FIGS. 41A-41B, second upper inner spacers 224B are formed on the sidewalls of the upper semiconductor nanostructures 166. The second upper inner spacers 224B may be formed of similar material(s) as the second lower inner spacers 124B, and may be formed by similar process(es) as those used to form the second lower inner spacers 124B (previously described for FIGS. 19A-19B).

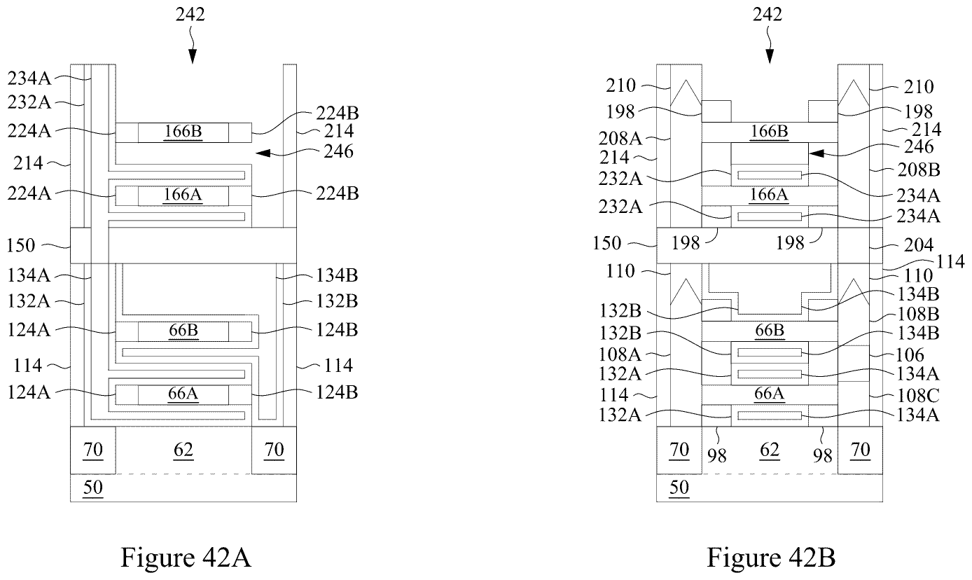

In FIGS. 42A-42B, the remaining portions of the second upper dummy nanostructures 164B are removed to form an opening 246 in a region between the second upper semiconductor nanostructure 166B and the first upper gate electrode 234A. The remaining portions of the second upper dummy nanostructures 164B can be removed by a similar process as that used to remove the second lower dummy nanostructures 64B (previously described for FIGS. 20A-20B).

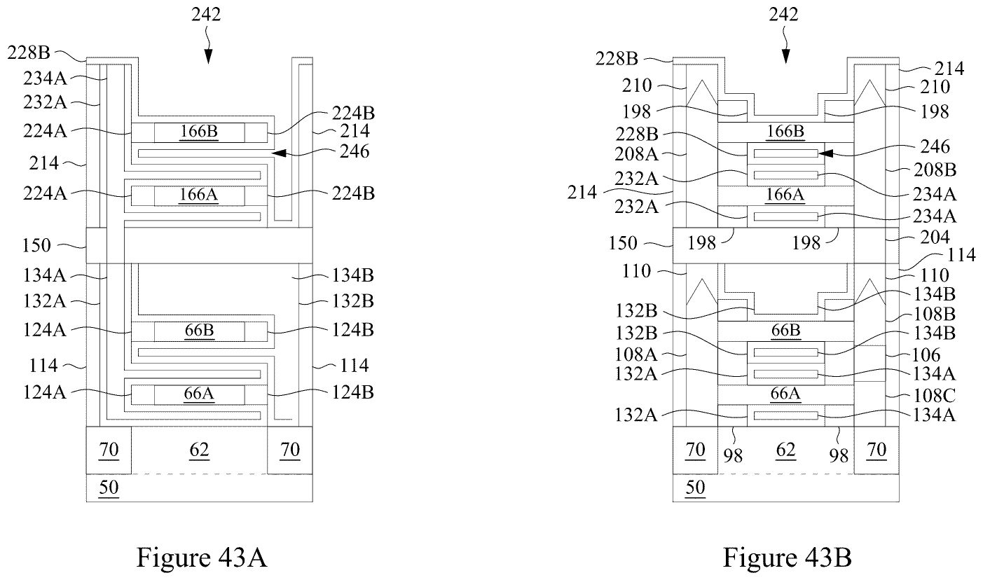

In FIGS. 43A-43B, one or more second gate dielectric layer(s) 228B are formed in the recess 242 and in the opening 246, as well as on the upper dielectric 214. The second gate dielectric layer(s) 228B are disposed on the top surface and the bottom surface of the second upper semiconductor nanostructure 166B; on the top surface of the isolation dielectric 150; on the sidewalls of the upper inner spacers 198; on the sidewalls of the second upper inner spacers 224B; on sidewalls and a top surface of the upper dielectric 214; and on sidewalls of the upper source/drain contacts 210. The second gate dielectric layer(s) 228B may be formed of similar material(s) as the second lower gate dielectric 132B, and may be formed by similar process(es) as those used to form the material(s) of the second lower gate dielectric 132B (previously described for FIGS. 21A-21B).

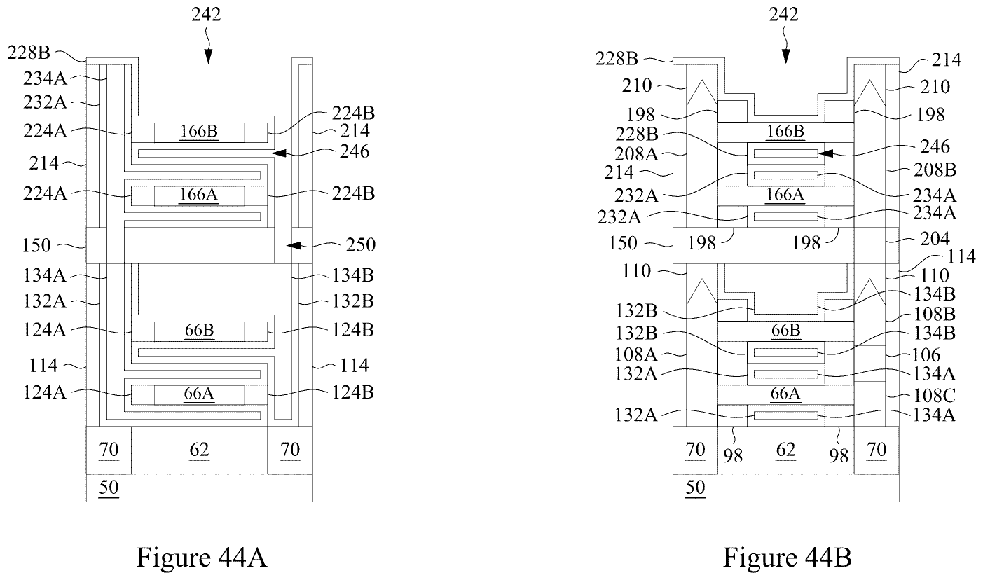

In FIGS. 44A-44B, an opening 250 is patterned in the second gate dielectric layer(s) 228B and the isolation dielectric 150, at the bottom of the recess 242. The opening 250 may be patterned using acceptable photolithography and etching techniques. The opening 250 exposes the second lower gate electrode 134B. The opening 250 is aligned with the recess 242.

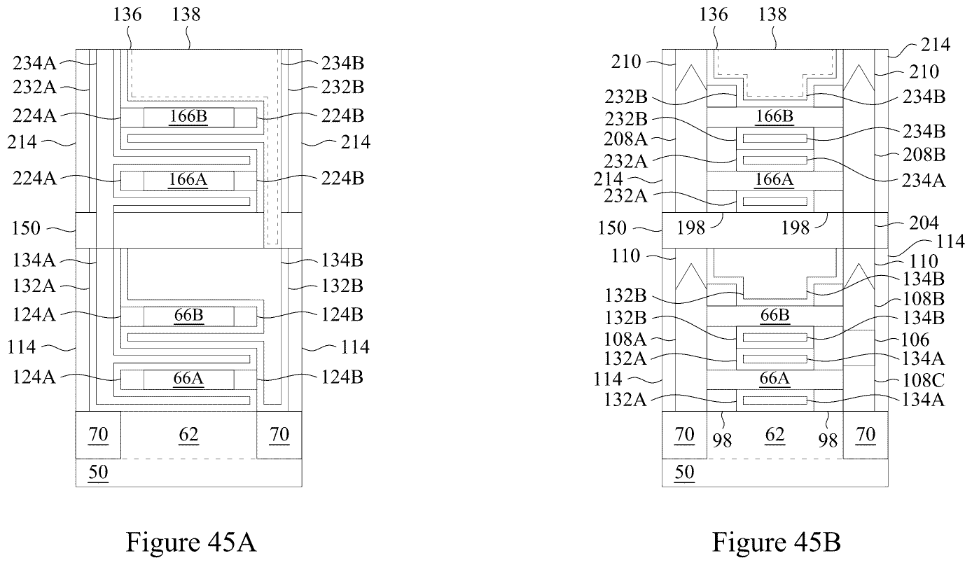

In FIGS. 45A-45B, a second upper gate electrode 234B is formed over the second gate dielectric layer(s) 228B and in the opening 250. The second upper gate electrode 234B may be formed of similar material(s) as the second lower gate electrode 134B, and may be formed by similar process(es) as those used to form the second lower gate electrode 134B (previously described for FIGS. 21A-21B). Additionally, a removal process is applied to the second gate dielectric layer(s) 228B to form a second upper gate dielectric 232B from portions of the second gate dielectric layer(s) 228B remaining in the recess 242 and the opening 246. The removal process may be performed when forming the second upper gate electrode 234B. The second upper gate electrode 234B may include a work function tuning layer 136 (of, e.g., titanium nitride) and a fill material 138 (of, e.g., tungsten), where the work function tuning layer 136 completely fills the portion of the opening 246 not filled by the second upper gate dielectric 232B, while the fill material 138 is disposed in the recess 242 and the opening 250 but in not the opening 246. The work function tuning layer 136 of the second upper gate electrode 234B is disposed between the fill material 138 of the second upper gate electrode 234B and the fill material of the second lower gate electrode 134B.

The second upper gate dielectric 232B and the second upper gate electrode 234B may be collectively referred to as a “second upper gate structure.” The second upper gate structure extends along a top surface and a bottom surface of the second upper semiconductor nanostructure 166B, and is disposed at a side of the second upper semiconductor nanostructure 166B. Thus, the second upper gate structure is around and controls three surfaces of the second upper semiconductor nanostructure 166B.

The second upper gate electrode 234B extends through the opening 250 in the isolation dielectric 150. Thus, the second upper gate electrode 234B contacts the second lower gate electrode 134B. Accordingly, the second lower gate electrode 134B and the second upper gate electrode 234B may be controlled together.

In FIGS. 46A-46B, an inter-layer dielectric (ILD) 254 is deposited over the upper source/drain contacts 210, the upper dielectric 214, the upper gate dielectrics 232, and the upper gate electrodes 234. In some embodiments, the ILD 254 is a flowable film formed by a flowable CVD method, which is subsequently cured. In some embodiments, the ILD 254 is formed of a dielectric material such as PSG, BSG, BPSG, USG, or the like, which may be deposited by any suitable method, such as CVD, PECVD, or the like.

In some embodiments, an etch stop layer (ESL) 252 is formed between the ILD 254 and the upper source/drain contacts 210, the upper dielectric 214, the upper gate dielectrics 232, and the upper gate electrodes 234. The ESL 252 may include a dielectric material having a high etching selectivity to the dielectric material of the ILD 254, such as silicon nitride, silicon oxide, silicon oxynitride, or the like.

Gate contacts 256 and source/drain vias 258 are formed through the ILD 254 to contact, respectively, the upper gate electrodes 234 and the upper source/drain contacts 210. The gate contacts 256 may be physically and electrically coupled to the upper gate electrodes 234. The source/drain vias 258 may be physically and electrically coupled to the upper source/drain contacts 210.

As an example to form the gate contacts 256 and the source/drain vias 258, openings for the gate contacts 256 and the source/drain vias 258 are formed through the ILD 254 and the ESL 252. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the ILD 254. The remaining liner and conductive material form the gate contacts 256 and the source/drain vias 258 in the openings. The gate contacts 256 and the source/drain vias 258 may be formed in distinct processes, or may be formed in the same process. It should be appreciated that each of the gate contacts 256 and the source/drain vias 258 may be formed in different cross-sections, which may avoid shorting of the contacts.

The structure shown in FIGS. 46A-46B includes four devices: a first lower nanostructure-FET 302, a second lower nanostructure-FET 304, a first upper nanostructure-FET 306, and a second upper nanostructure-FET 308. The second lower nanostructure-FET 304 is stacked over the first lower nanostructure-FET 302. The second upper nanostructure-FET 308 is stacked over the first upper nanostructure-FET 306. Additionally, the first upper nanostructure-FET 306 and the second upper nanostructure-FET 308 are stacked over the first lower nanostructure-FET 302 and the second lower nanostructure-FET 304. The stacked transistors may be interconnected to form logic devices, such as Boolean logic gates (e.g., NAND gates, NOR gates, NOT gates, etc.).

The nanostructure-FETs may be interconnected by metallization layers in an overlying interconnect structure to form integrated circuits, including Boolean logic gates. For example, the metallization layers may include control interconnects, which are coupled to the gate structures. The overlying interconnect structure can be formed in a back end of line (BEOL) process, in which the metallization layers are connected to the gate contacts 256 and the source/drain vias 258. Additional features, such as passive devices, memories, or the like may be integrated with the interconnect structure during the BEOL process.

In this embodiment, the first lower nanostructure-FET 302 includes the first lower gate structure (including the first lower gate dielectric 132A and the first lower gate electrode 134A), the first lower semiconductor nanostructure 66A, the first lower epitaxial source/drain region 108A, and the third lower epitaxial source/drain region 108C. The first lower gate structure extends along the top and bottom surfaces of the first lower semiconductor nanostructure 66A. The first lower gate structure is also along the first side of the lower semiconductor nanostructures 66 in the cross-section of FIG. 46A, with the first lower inner spacers 124A disposed between the first lower gate structure and the first sidewalls of the lower semiconductor nanostructures 66.

In this embodiment, the second lower nanostructure-FET 304 includes the second lower gate structure (including the second lower gate dielectric 132B and the second lower gate electrode 134B), the second lower semiconductor nanostructure 66B, the first lower epitaxial source/drain region 108A, and the second lower epitaxial source/drain region 108B. The second lower gate structure extends along the top and bottom surfaces of the second lower semiconductor nanostructure 66B. The second lower gate structure is also along the second side of the lower semiconductor nanostructures 66 in the cross-section of FIG. 46A, with the second lower inner spacers 124B disposed between the second lower gate structure and the second sidewalls of the lower semiconductor nanostructures 66.

In this embodiment, the first upper nanostructure-FET 306 includes the first upper gate structure (including the first upper gate dielectric 232A and the first upper gate electrode 234A), the first upper semiconductor nanostructure 166A, the first upper epitaxial source/drain region 208A, and the second upper epitaxial source/drain region 208B. The first upper gate structure extends along the top and bottom surfaces of the first upper semiconductor nanostructure 166A. The first upper gate structure is also along the first side of the upper semiconductor nanostructures 166 in the cross-section of FIG. 46A, with the first upper inner spacers 224A disposed between the first upper gate structure and the first sidewalls of the upper semiconductor nanostructures 166.

In this embodiment, the second upper nanostructure-FET 308 includes the second upper gate structure (including the second upper gate dielectric 232B and the second upper gate electrode 234B), the second upper semiconductor nanostructure 166B, the first upper epitaxial source/drain region 208A, and the second upper epitaxial source/drain region 208B. The second upper gate structure extends along the top and bottom surfaces of the second upper semiconductor nanostructure 166B. The second upper gate structure is also along the second side of the upper semiconductor nanostructures 166 in the cross-section of FIG. 46A, with the second upper inner spacers 224B disposed between the second upper gate structure and the second sidewalls of the upper semiconductor nanostructures 166.

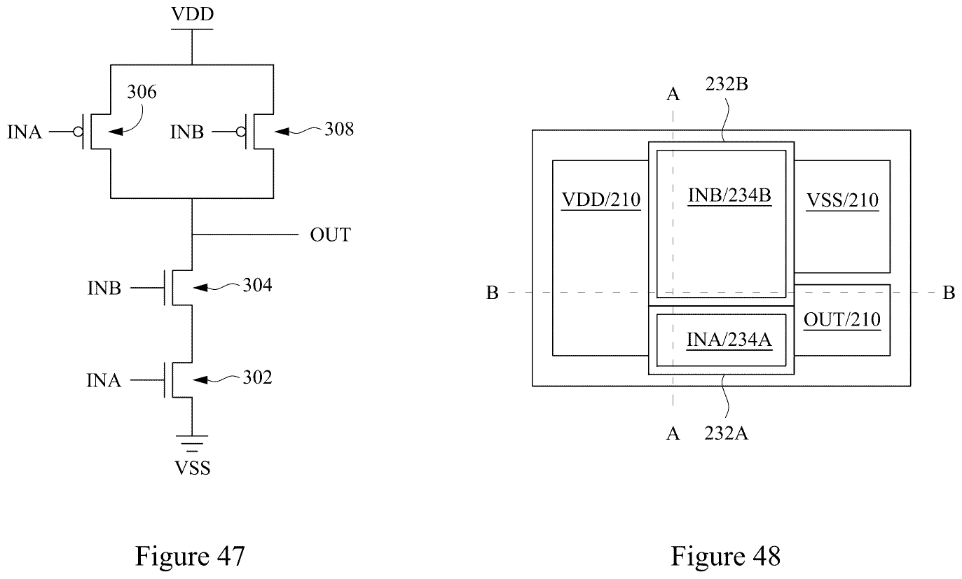

As previously noted, the stacked transistors may be interconnected to form Boolean logic gates. In this embodiment, the nanostructure-FETs 302, 304, 306, 308 are part of a NAND gate, which is schematically shown in FIG. 47. FIG. 48 is a top-down view of the NAND gate, in accordance with some embodiments. Reference cross-sections A-A′ and B-B′ in FIG. 48 are similar to the cross-sections along which FIGS. 46A and 46B, respectively, are illustrated. The first lower nanostructure-FET 302 and the second lower nanostructure-FET 304 are connected in series, as a result of the lower isolation dielectric 106 being between the second lower epitaxial source/drain region 108B and the third lower epitaxial source/drain region 108C while the lower nanostructure-FETs share the first lower epitaxial source/drain region 108A. The first upper nanostructure-FET 306 and the second upper nanostructure-FET 308 are connected in parallel, as a result of the upper nanostructure-FETs sharing both the first upper epitaxial source/drain region 208A and the second upper epitaxial source/drain region 208B. The first upper epitaxial source/drain region 208A is coupled to a supply voltage VDD, while the third lower epitaxial source/drain region 108C is coupled to a reference voltage VSS. The first lower gate electrode 134A and the first upper gate electrode 234A are coupled together to form a first input INA of the NAND gate. The second lower gate electrode 134B and the second upper gate electrode 234B are coupled together to form a second input INB of the NAND gate. The second upper epitaxial source/drain region 208B and the second lower epitaxial source/drain region 108B are coupled together by the lower source/drain via 204 to form an output OUT of the NAND gate.

In this embodiment, a first stack of gate structures (e.g., the first lower gate electrode 134A and the first upper gate electrode 234A) are coupled to a first control interconnect, while a second stack of gate structures (e.g., the second lower gate electrode 134B and the second upper gate electrode 234B) are coupled to a second control interconnect. The first control interconnect and the second control interconnect are different control interconnects, such that the respective stacks of gate structures may be separately controlled. In another embodiment, the first stack of gate structures (e.g., the first lower gate electrode 134A and the first upper gate electrode 234A) and the second stack of gate structures (e.g., the second lower gate electrode 134B and the second upper gate electrode 234B) are coupled to the same control interconnect, such that the respective stacks of gate structures may be controlled together.

Embodiments may achieve advantages. Because the nanostructure-FETs 302, 304, 306, 308 are stacked, they have a small footprint. Specifically, the resulting Boolean logic gate may have a one-transistor (1T) footprint, even when the Boolean logic gate includes four transistors. Forming the isolation dielectrics 106, 150 between some of the source/drain regions (but not others) allows desired ones of the source/drain regions to be vertically isolated, which may allow various ones of the nanostructure-FETs to be connected in series or in parallel, as desired.

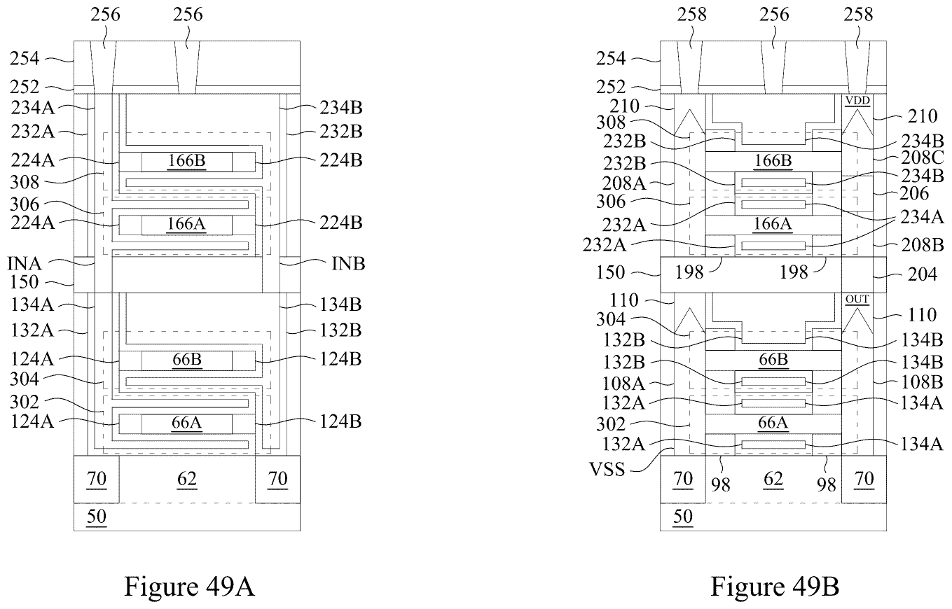

FIGS. 49A-49B are views of stacked transistors, in accordance with some other embodiments. This embodiment is similar to the embodiment of FIGS. 46A-46B, except the lower epitaxial source/drain regions 108 include a first lower epitaxial source/drain region 108A and a second lower epitaxial source/drain region 108B. The first lower epitaxial source/drain region 108A and the second lower epitaxial source/drain region 108B are each shared between the first lower nanostructure-FET 302 and the second lower nanostructure-FET 304. Additionally, the upper epitaxial source/drain regions 208 include a first upper epitaxial source/drain region 208A, a second upper epitaxial source/drain region 208B, and a third upper epitaxial source/drain region 208C. An upper isolation dielectric 206 may be formed between the second upper epitaxial source/drain region 208B and the third upper epitaxial source/drain region 208C. The upper isolation dielectric 206 may be formed of similar material(s) as the lower isolation dielectric 106, and may be formed by similar process(es) as those used to form the lower isolation dielectric 106 (previously described for FIGS. 11A-11B). The first upper epitaxial source/drain region 208A is shared between the first upper nanostructure-FET 306 and the second upper nanostructure-FET 308.

In this embodiment, the first lower nanostructure-FET 302 includes the first lower gate structure (including the first lower gate dielectric 132A and the first lower gate electrode 134A), the first lower semiconductor nanostructure 66A, the first lower epitaxial source/drain region 108A, and the second lower epitaxial source/drain region 108B. Likewise, the second lower nanostructure-FET 304 includes the second lower gate structure (including the second lower gate dielectric 132B and the second lower gate electrode 134B), the second lower semiconductor nanostructure 66B, the first lower epitaxial source/drain region 108A, and the second lower epitaxial source/drain region 108B. Additionally, the first upper nanostructure-FET 306 includes the first upper gate structure (including the first upper gate dielectric 232A and the first upper gate electrode 234A), the first upper semiconductor nanostructure 166A, the first upper epitaxial source/drain region 208A, and the second upper epitaxial source/drain region 208B. Finally, the second upper nanostructure-FET 308 includes the second upper gate structure (including the second upper gate dielectric 232B and the second upper gate electrode 234B), the second upper semiconductor nanostructure 166B, the first upper epitaxial source/drain region 208A, and the third upper epitaxial source/drain region 208C.

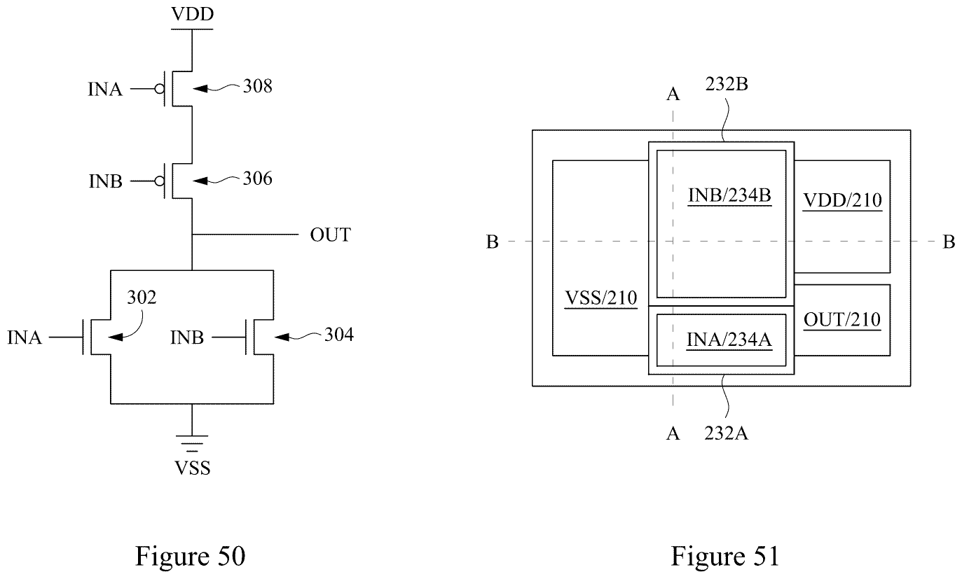

As previously noted, the stacked transistors may be interconnected to form Boolean logic gates. In this embodiment, the nanostructure-FETs 302, 304, 306, 308 are part of a NOR gate, which is schematically shown in FIG. 50. FIG. 51 is a top-down view of the NOR gate, in accordance with some embodiments. Reference cross-sections A-A′ and B-B′ in FIG. 51 are similar to the cross-sections along which FIGS. 49A and 49B, respectively, are illustrated. The first lower nanostructure-FET 302 and the second lower nanostructure-FET 304 are connected in parallel, as a result of the lower nanostructure-FETs sharing both the first lower epitaxial source/drain region 108A and the second lower epitaxial source/drain region 108B. The first upper nanostructure-FET 306 and the second upper nanostructure-FET 308 are connected in series, as a result of the upper isolation dielectric 206 being between the second upper epitaxial source/drain region 208B and the third upper epitaxial source/drain region 208C while the upper nanostructure-FETs share the first upper epitaxial source/drain region 208A. The second upper epitaxial source/drain region 208B is coupled to a supply voltage VDD, while the first lower epitaxial source/drain region 108A is coupled to a reference voltage VSS. The first lower gate electrode 134A and the first upper gate electrode 234A are coupled together to form a first input INA of the NOR gate. The second lower gate electrode 134B and the second upper gate electrode 234B are coupled together to form a second input INB of the NOR gate. The second lower epitaxial source/drain region 108B and the second upper epitaxial source/drain region 208B are coupled together by the lower source/drain via 204 to form an output OUT of the NOR gate.

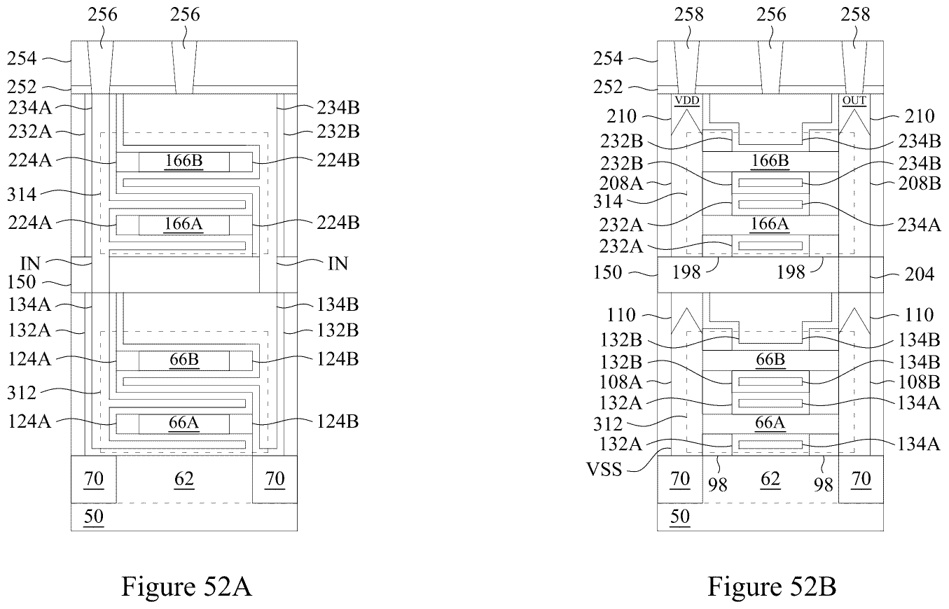

FIGS. 52A-52B are views of stacked transistors, in accordance with some other embodiments. This embodiment is similar to the embodiment of FIGS. 46A-46B, except the structure shown includes two devices: a lower nanostructure-FET 312 and an upper nanostructure-FET 314. The lower epitaxial source/drain regions 108 include a first lower epitaxial source/drain region 108A and a second lower epitaxial source/drain region 108B. Additionally, the upper epitaxial source/drain regions 208 include a first upper epitaxial source/drain region 208A and a second upper epitaxial source/drain region 208B.

In this embodiment, the lower nanostructure-FET 312 includes the first lower gate structure (including the first lower gate dielectric 132A and the first lower gate electrode 134A), the second lower gate structure (including the second lower gate dielectric 132B and the second lower gate electrode 134B), the lower semiconductor nanostructures 66 (including the first lower semiconductor nanostructure 66A and the second lower semiconductor nanostructure 66B), the first lower epitaxial source/drain region 108A, and the second lower epitaxial source/drain region 108B. Likewise, the upper nanostructure-FET 314 includes the first upper gate structure (including the first upper gate dielectric 232A and the first upper gate electrode 234A), the second upper gate structure (including the second upper gate dielectric 232B and the second upper gate electrode 234B), the upper semiconductor nanostructures 166 (including the first upper semiconductor nanostructure 166A and the second upper semiconductor nanostructure 166B), the first upper epitaxial source/drain region 208A, and the second upper epitaxial source/drain region 208B.

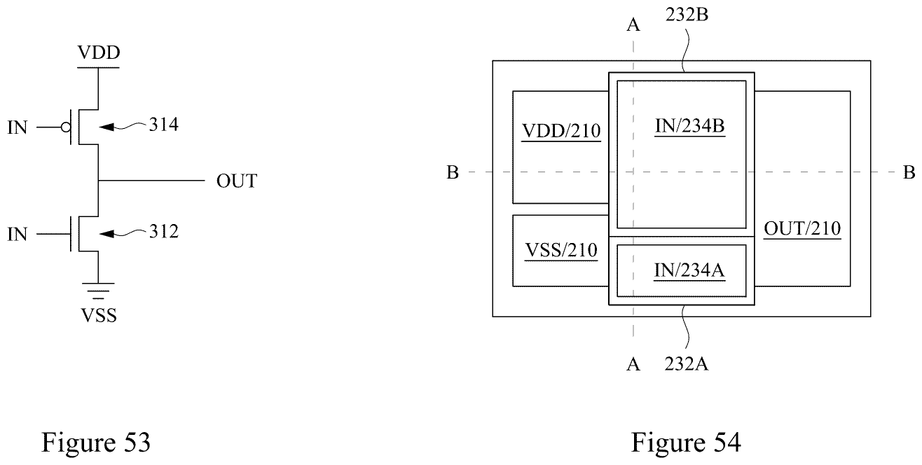

As previously noted, the stacked transistors may be interconnected to form Boolean logic gates. In this embodiment, the nanostructure-FETs 312, 314 are part of a NOT gate, which is schematically shown in FIG. 53. FIG. 54 is a top-down view of the NOT gate, in accordance with some embodiments. Reference cross-sections A-A′ and B-B′ in FIG. 54 are similar to the cross-sections along which FIGS. 52A and 52B, respectively, are illustrated. The lower nanostructure-FET 312 and the upper nanostructure-FET 314 are connected in series. The first upper epitaxial source/drain region 208A is coupled to a supply voltage VDD, while the first lower epitaxial source/drain region 108A is coupled to a reference voltage VSS. The first lower gate electrode 134A, the first upper gate electrode 234A, the second lower gate electrode 134B, and the second upper gate electrode 234B are coupled together (e.g., by upper-level interconnects) to form an input IN of the NOT gate. The second upper epitaxial source/drain region 208B and the second lower epitaxial source/drain region 108B are coupled together by the lower source/drain via 204 to form an output OUT of the NOT gate.

The previously described Boolean logic gates may be interconnected to form other logic devices. For example, four NAND gates may be interconnected (e.g., by upper-level interconnects) to form an XOR gate. Additionally, the structure may have any desired quantity of stacked channel regions. In some embodiments, the structure has from 4 to 100 stacked channel regions.

In an embodiment, a device includes: a first nanostructure; a second nanostructure above the first nanostructure; a first gate structure extending along a top surface and a bottom surface of the first nanostructure, the first gate structure disposed at a first side of the first nanostructure and a first side of the second nanostructure; and a second gate structure extending along a top surface and a bottom surface of the second nanostructure, the second gate structure disposed at a second side of the first nanostructure and a second side of the second nanostructure, the second side of the first nanostructure opposite the first side of the first nanostructure, the second side of the second nanostructure opposite the first side of the second nanostructure. In some embodiments of the device, the first nanostructure and the second nanostructure have the same conductivity type. In some embodiments of the device, the first gate structure and the second gate structure are coupled to different control interconnects. In some embodiments of the device, the first gate structure and the second gate structure are coupled to the same control interconnect. In some embodiments, the device further includes: a first source/drain region adjacent the first nanostructure and the second nanostructure; a second source/drain region adjacent the second nanostructure; a third source/drain region adjacent the first nanostructure; and an isolation dielectric between the third source/drain region and the second source/drain region. In some embodiments, the device further includes: a first source/drain region adjacent the first nanostructure and the second nanostructure; and a second source/drain region adjacent the first nanostructure and the second nanostructure. In some embodiments of the device, a first top surface of the first gate structure is substantially coplanar with a second top surface of the second gate structure.

In an embodiment, a device includes: a first lower nanostructure-FET including a first lower semiconductor nanostructure and a first lower gate structure around the first lower semiconductor nanostructure; a second lower nanostructure-FET including a second lower semiconductor nanostructure and a second lower gate structure around the second lower semiconductor nanostructure, the second lower semiconductor nanostructure disposed above the first lower semiconductor nanostructure; a first upper nanostructure-FET including a first upper semiconductor nanostructure and a first upper gate structure around the first upper semiconductor nanostructure, the first upper semiconductor nanostructure disposed above the second lower semiconductor nanostructure, the first upper gate structure coupled to the first lower gate structure; and a second upper nanostructure-FET including a second upper semiconductor nanostructure and a second upper gate structure around the second upper semiconductor nanostructure, the second upper semiconductor nanostructure disposed above the first upper semiconductor nanostructure, the second upper gate structure coupled to the second lower gate structure. In some embodiments of the device, the first lower nanostructure-FET further includes a lower source/drain region, the second lower nanostructure-FET further includes the lower source/drain region, the first upper nanostructure-FET further includes an upper source/drain region, and the second upper nanostructure-FET further includes the upper source/drain region. In some embodiments, the device further includes: an isolation dielectric between the lower source/drain region and the upper source/drain region, the first upper gate structure and the second upper gate structure each extending through the isolation dielectric. In some embodiments of the device, the first lower nanostructure-FET and the second lower nanostructure-FET are connected in series, and the first upper nanostructure-FET and the second upper nanostructure-FET are connected in parallel. In some embodiments of the device, the first lower nanostructure-FET, the second lower nanostructure-FET, the first upper nanostructure-FET, and the second upper nanostructure-FET are part of a NAND gate. In some embodiments of the device, the first lower nanostructure-FET and the second lower nanostructure-FET are connected in parallel, and the first upper nanostructure-FET and the second upper nanostructure-FET are connected in series. In some embodiments of the device, the first lower nanostructure-FET, the second lower nanostructure-FET, the first upper nanostructure-FET, and the second upper nanostructure-FET are part of a NOR gate.

In an embodiment, a method includes: forming a first semiconductor nanostructure, a second semiconductor nanostructure, first dummy nanostructures, and second dummy nanostructures, the first semiconductor nanostructure disposed between the first dummy nanostructures, the second semiconductor nanostructure disposed between the second dummy nanostructures; forming a first source/drain region adjacent the first semiconductor nanostructure and the second semiconductor nanostructure in a first cross-section; replacing the first dummy nanostructures with a first gate structure, the first gate structure disposed at a first side of the first semiconductor nanostructure and a first side of the second semiconductor nanostructure in a second cross-section, where the first cross-section is different from the second cross-section; and after replacing the first dummy nanostructures, replacing the second dummy nanostructures with a second gate structure, the second gate structure disposed at a second side of the first semiconductor nanostructure and a second side of the second semiconductor nanostructure in the second cross-section. In some embodiments, the method further includes: forming a second source/drain region adjacent the first semiconductor nanostructure in the first cross-section; forming an isolation dielectric on the second source/drain region; and forming a third source/drain region on the isolation dielectric and adjacent the second semiconductor nanostructure in the first cross-section. In some embodiments, the method further includes: forming a second source/drain region adjacent the first semiconductor nanostructure and the second semiconductor nanostructure in the first cross-section. In some embodiments, the method further includes: forming a second source/drain region adjacent the first semiconductor nanostructure; and forming an isolation dielectric over the first source/drain region, the second source/drain region, the first gate structure, and the second gate structure. In some embodiments, the method further includes: forming a via through the isolation dielectric, the via connected to the second source/drain region. In some embodiments of the method, the first semiconductor nanostructure and the second semiconductor nanostructure have the same conductivity type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first semiconductor nanostructure and a second semiconductor nanostructure, the first semiconductor nanostructure and the second semiconductor nanostructure being vertically stacked over a substrate;
forming a dielectric material around the first semiconductor nanostructure and the second semiconductor nanostructure;
forming a first gate structure in the dielectric material, the first gate structure extending along a top surface and a bottom surface of the first semiconductor nanostructure; and
forming a second gate structure in the dielectric material, the second gate structure extending along a top surface and a bottom surface of the second semiconductor nanostructure, the first gate structure separated from the second gate structure.

2. The method of claim 1, further comprising:
forming a first source/drain region, a second source/drain region, and a third source/drain region, the first semiconductor nanostructure disposed between the first source/drain region and the second source/drain region, the second semiconductor nanostructure disposed between the first source/drain region and the third source/drain region, wherein the dielectric material is also formed around the first source/drain region, the second source/drain region, and the third source/drain region.

3. The method of claim 1, further comprising:
forming a first source/drain region and a second source/drain region, the first semiconductor nanostructure disposed between the first source/drain region and the second source/drain region, the second semiconductor nanostructure disposed between the first source/drain region and the second source/drain region, wherein the dielectric material is also formed around the first source/drain region and the second source/drain region.

4. The method of claim 1, further comprising:
forming a first source/drain region and a second source/drain region, the first semiconductor nanostructure disposed between the first source/drain region and the second source/drain region;
depositing an isolation dielectric over the first source/drain region, the second source/drain region, the first gate structure, and the second gate structure; and
forming a conductive via through the isolation dielectric, the conductive via connected to the second source/drain region, the first source/drain region covered by the isolation dielectric.

5. The method of claim 1, wherein the first semiconductor nanostructure and the second semiconductor nanostructure have the same conductivity type.

6. The method of claim 1, wherein a top surface of the dielectric material is coplanar with a top surface of the first gate structure and a top surface of the second gate structure.

7. The method of claim 1, wherein forming the first semiconductor nanostructure and the second semiconductor nanostructure comprises:
forming a multi-layer stack comprising alternating semiconductor layers and dummy layers;
patterning the multi-layer stack to form a stack of alternating semiconductor nanostructures and dummy nanostructures; and
removing the dummy nanostructures while maintaining the semiconductor nanostructures.

8. The method of claim 1, further comprising:
forming an isolation dielectric over the first gate structure and the second gate structure;
forming a third semiconductor nanostructure and a fourth semiconductor nanostructure, the third semiconductor nanostructure and the fourth semiconductor nanostructure being vertically stacked over the isolation dielectric;
forming a third gate structure extending along a top surface and a bottom surface of the third semiconductor nanostructure, the third gate structure coupled to the first gate structure; and
forming a fourth gate structure extending along a top surface and a bottom surface of the fourth semiconductor nanostructure, the fourth gate structure coupled to the second gate structure, the third gate structure separated from the fourth gate structure.

9. The method of claim 8, wherein the third gate structure is formed through the isolation dielectric, and the fourth gate structure is formed through the isolation dielectric.

10. A method comprising:
forming an isolation dielectric over a first gate structure and a second gate structure;
forming a first semiconductor nanostructure and a second semiconductor nanostructure, the first semiconductor nanostructure and the second semiconductor nanostructure being vertically stacked over the isolation dielectric;
patterning a first opening in the isolation dielectric, the first opening exposing the first gate structure;
forming a third gate structure in the first opening and around the first semiconductor nanostructure, the third gate structure contacting the first gate structure;
patterning a second opening in the isolation dielectric, the second opening exposing the second gate structure; and
forming a fourth gate structure in the second opening and around the second semiconductor nanostructure, the fourth gate structure contacting the second gate structure.

11. The method of claim 10, further comprising:
forming first spacers on first sidewalls of the first semiconductor nanostructure and the second semiconductor nanostructure, the third gate structure being formed along the first spacers; and
forming second spacers on second sidewalls of the first semiconductor nanostructure and the second semiconductor nanostructure, the fourth gate structure being formed along the second spacers.

12. The method of claim 10, wherein the first semiconductor nanostructure and the second semiconductor nanostructure have the same conductivity type.

13. The method of claim 10, further comprising:
interconnecting the first gate structure, the second gate structure, the third gate structure, and the fourth gate structure to form a Boolean logic gate.

14. A method comprising:
forming a first semiconductor nanostructure and a second semiconductor nanostructure, the first semiconductor nanostructure and the second semiconductor nanostructure being vertically stacked over a substrate;
forming a first gate structure extending along a top surface and a bottom surface of the first semiconductor nanostructure;
forming a second gate structure extending along a top surface and a bottom surface of the second semiconductor nanostructure, the first gate structure separated from the second gate structure;
forming an isolation dielectric over the first gate structure and the second gate structure;
forming a third semiconductor nanostructure and a fourth semiconductor nanostructure, the third semiconductor nanostructure and the fourth semiconductor nanostructure being vertically stacked over the isolation dielectric;
forming a third gate structure extending along a top surface and a bottom surface of the third semiconductor nanostructure, the third gate structure extending through the isolation dielectric to contact the first gate structure; and
forming a fourth gate structure extending along a top surface and a bottom surface of the fourth semiconductor nanostructure, the fourth gate structure extending through the isolation dielectric to contact the second gate structure, the third gate structure separated from the fourth gate structure.

15. The method of claim 14, further comprising:
forming a first source/drain region adjacent to both the first semiconductor nanostructure and the second semiconductor nanostructure, the isolation dielectric also being formed over the first source/drain region; and
forming a second source/drain region adjacent to both the third semiconductor nanostructure and the fourth semiconductor nanostructure, the isolation dielectric separating the first source/drain region from the second source/drain region.

16. The method of claim 14, further comprising:
forming a first source/drain region adjacent to both the first semiconductor nanostructure and the second semiconductor nanostructure, the isolation dielectric also being formed over the first source/drain region;
forming a conductive via extending through the isolation dielectric; and
forming a second source/drain region adjacent to both the third semiconductor nanostructure and the fourth semiconductor nanostructure, the conductive via connecting the second source/drain region to the first source/drain region.

17. The method of claim 14, further comprising:
forming a first source/drain region adjacent to both the first semiconductor nanostructure and the second semiconductor nanostructure, the isolation dielectric also being formed over the first source/drain region;
forming a conductive via extending through the isolation dielectric;
forming a second source/drain region adjacent to the third semiconductor nanostructure, the conductive via connecting the second source/drain region to the first source/drain region; and
forming a third source/drain region adjacent to the fourth semiconductor nanostructure.

18. The method of claim 14, further comprising:
forming a first source/drain region adjacent to the first semiconductor nanostructure;
forming a second source/drain region adjacent to the second semiconductor nanostructure, the isolation dielectric also being formed over the second source/drain region;
forming a conductive via extending through the isolation dielectric; and
forming a third source/drain region adjacent to both the third semiconductor nanostructure and the fourth semiconductor nanostructure, the conductive via connecting the third source/drain region to the second source/drain region.

19. The method of claim 14, wherein the first gate structure and the second gate structure are formed at opposing sides of the first semiconductor nanostructure and at opposing sides of the second semiconductor nanostructure, and the third gate structure and the fourth gate structure are formed at opposing sides of the third semiconductor nanostructure and at opposing sides of the fourth semiconductor nanostructure.

20. The method of claim 14, wherein the first semiconductor nanostructure and the second semiconductor nanostructure have a first conductivity type, and the third semiconductor nanostructure and the fourth semiconductor nanostructure have a second conductivity type opposite to the first conductivity type.
